(19) United States
(12) Patent Application Publication
(10) Pub. No.: US 2025/0240578 A1
(43) Pub. Date: Jul. 24, 2025

(54) MICRO-ELECTROMECHANICAL MICROPHONES AND METHODS OF FORMING THE SAME

(71) Applicant: Taiwan Semiconductor Manufacturing Company, Ltd., Hsinchu (TW)

(72) Inventor: Ting-Jung CHEN, Hsinchu County (TW)

(21) Appl. No.: 18/420,232

(22) Filed: Jan. 23, 2024

(51) Int. Cl. H04R 17/02; B81B 7/02; B81C 1/00; H04R 23/00; H10N 30/06

(52) U.S. Cl. CPC H04R 17/02; B81B 7/02; B81C 1/00166; B81C 1/00523; H04R 23/006; H10N 30/06; B81C 2201/013; H04R 2201/003

(57) ABSTRACT

An approximate S-shape is formed in a non-sensing portion of a micro-electromechanical systems (MEMS) microphone. For example, a piezo-electric layer, in a semiconductor stack forming the non-sensing portion, may have a lower portion at a first point that is at least 1 micrometer (μm) below the lower portion at a second point. The approximately S-shape reinforces a piezo-membrane including the non-sensing portion and results in mismatch between petals of the piezo-membrane remaining closer to zero (e.g., within 6 μm). As a result, fewer incoming sound waves leak through a gap between petals of the piezo-membrane, and performance of the MEMS microphone is increased. Additionally, the gap between the petals is less likely to allow dust and other small particles to enter the MEMS microphone, which further improves performance of the MEMS microphone.

### BACKGROUND

Micro-electromechanical systems (MEMS), which may include devices like microphones, are becoming increasingly common in modern devices (e.g., smart speakers, hearing aids, and microphones). MEMS microphones convert sound waves into electrical signals for processing. Some MEMS microphones use a piezo-electric structure that converts mechanical strains into electrical signals. Piezo-electric-based MEMS microphones generally provide a high signal-to-noise ratio and are less sensitive to particles and moisture as compared to other types of MEMS microphones.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of example semiconductor structures described herein.

FIGS. 3A-3R are diagrams of an example implementation described herein.

FIGS. 4A-4P are diagrams of an example implementation described herein.

FIG. 5A is a diagram of example mismatches described herein.

FIG. 5B is a diagram of example deflections described herein.

FIG. 6 is a diagram of example components of one or more devices of FIG. 1 described herein.

FIG. 7 is a flowchart of an example process associated with forming a semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A condenser microphone generally includes a moveable membrane and a stationary backplate. An incoming sound wave distorts the membrane, which results in changes in capacitance between the membrane and the backplate. Accordingly, an electrical signal can be generated, based on the changes in capacitance, that encodes the incoming sound wave.

In a piezo-electric-based micro-electromechanical systems (MEMS) microphone, the membrane and backplate may be replaced with a thin piezo-membrane formed of stacked semiconductor materials. A flexible portion of the piezo-membrane may physically move in response to an incoming sound wave, which results in changes in electrical charge in a stationary portion of the piezo-membrane.

The flexible portion of the piezo-membrane may be separated into multiple petals. However, when the petals of the piezo-membrane become too physically separated from each other (e.g., more than 6 micrometers (μm)), incoming sound waves may leak through a gap between the petals. As a result, performance of the MEMS microphone is reduced.

Additionally, the gap between the petals may allow dust and other small particles to enter the MEMS microphone and affect measurements of future sound waves, which further degrades performance of the MEMS microphone.

Some implementations described herein provide techniques and apparatuses for forming an approximate S-shape in a flexible portion of a piezo-membrane in a MEMS microphone. For example, a semiconductor layer, in a stack forming the stationary portion of a piezo-membrane, may have a lower portion at a first point that is at least 1 μm below the lower portion at a second point. Because the piezo-membrane is reinforced, mismatch between petals of the piezo-membrane remains closer to zero (e.g., within 6 μm). As a result, fewer incoming sound waves leak through a gap between the petals, and performance of the MEMS microphone is increased. Additionally, the gap between the petals is less likely to allow dust and other small particles to enter the MEMS microphone, which further improves performance of the MEMS microphone.

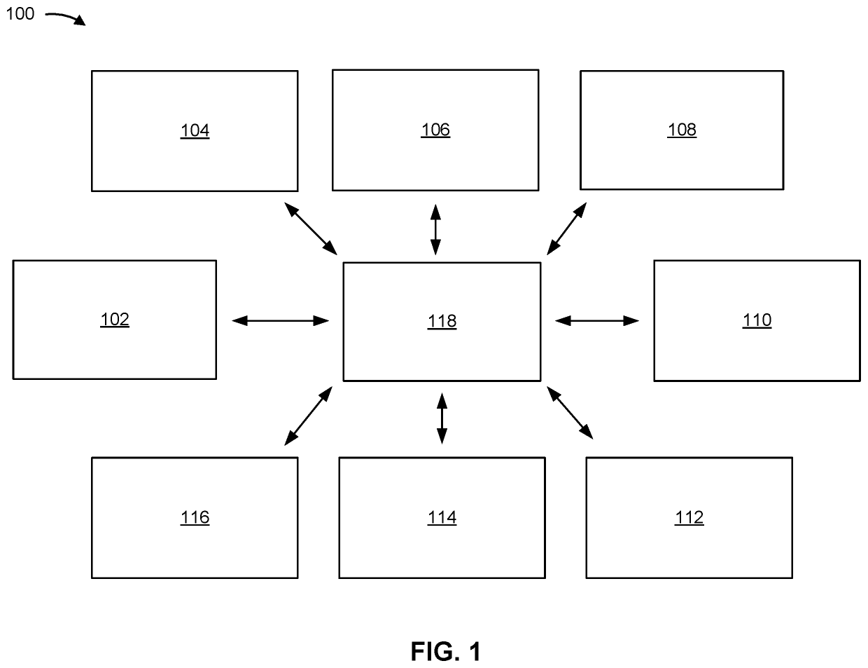

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, a photoresist removal tool 114, a singulation tool 116, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The photoresist removal tool 114 is a semiconductor processing tool that is capable of removing remaining portions of a photoresist layer from a substrate after the etch tool 108 removes portions of the substrate. For example, the photoresist removal tool 114 may use a chemical stripper and/or another technique to remove a photoresist layer from a substrate.

The singulation tool 116 is a semiconductor processing tool that is capable of singulating (e.g., separating, removing) one or more integrated circuit dies from a wafer. For example, the singulation tool 116 may include a dicing tool, a sawing tool, and/or or a laser tool that cuts one or more integrated circuit (IC) dies from a wafer, among other examples.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may form a mask over a dielectric layer; etch the dielectric layer, using the mask, to form an approximate S-shape; remove the mask; form a piezo-membrane comprising a semiconductor stack; and/or remove, from under a portion of the semiconductor stack that is configured to move in response to sound waves, a portion of the dielectric layer.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

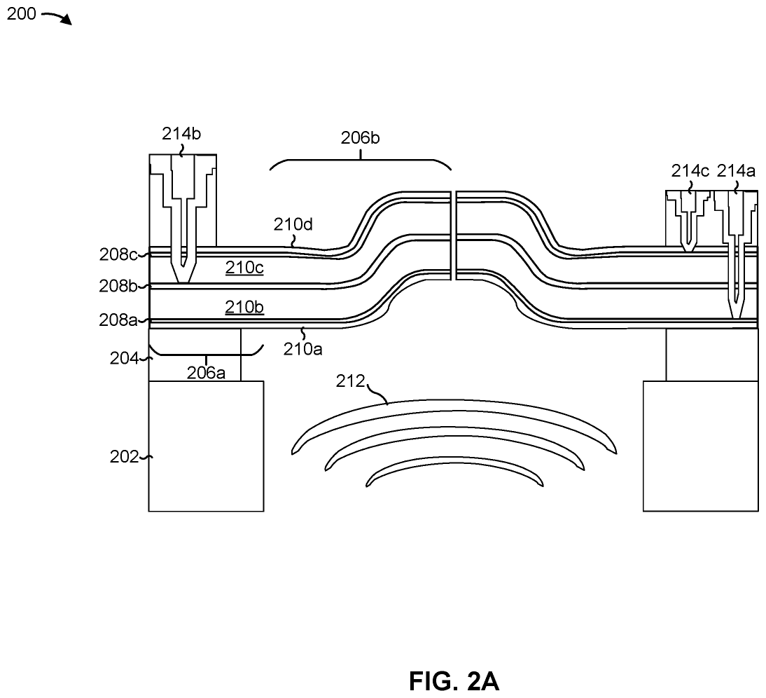

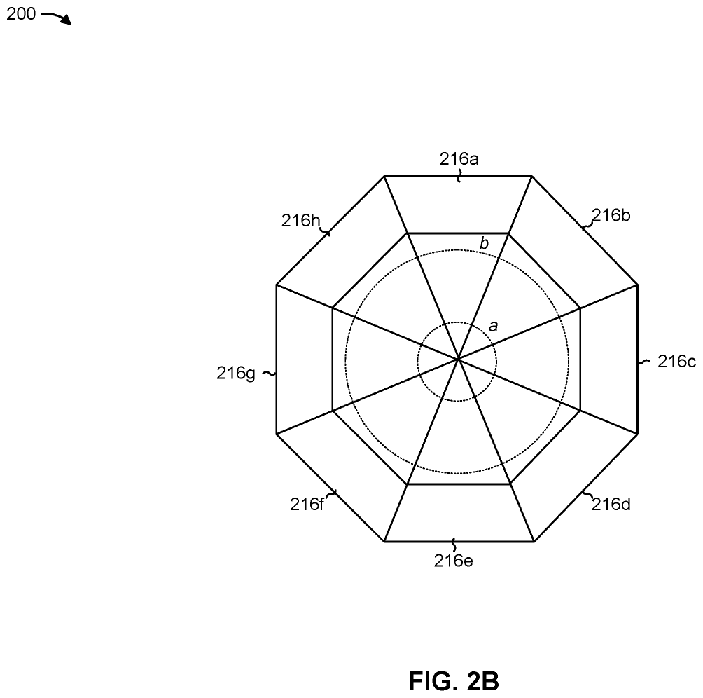

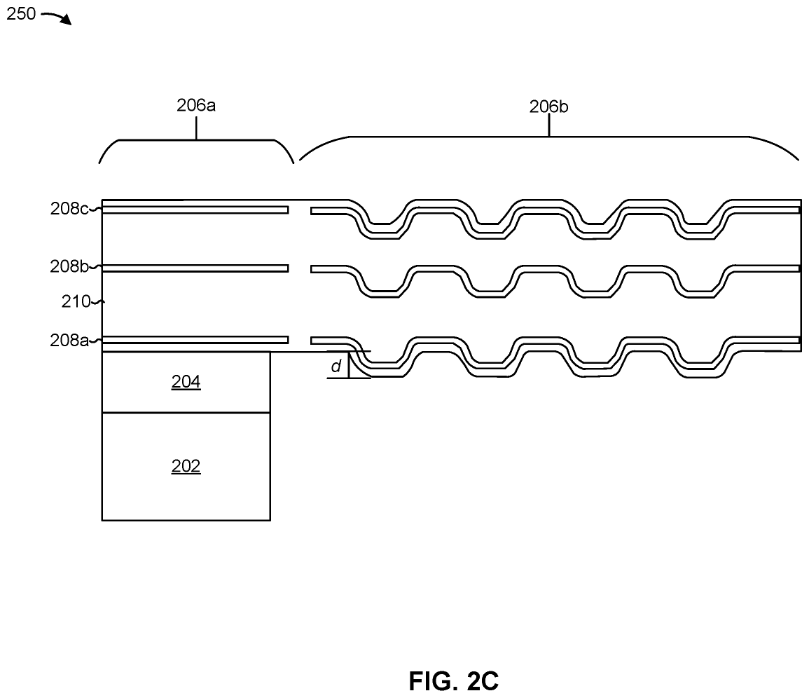

FIGS. 2A and 2B are diagrams of an example semiconductor structure 200 described herein. In particular, FIG. 2A illustrates a cross-section view of the example semiconductor structure 200. The example semiconductor structure 200 may be included in a MEMS microphone (e.g., a piezo-electric-based MEMS microphone) and/or another type of semiconductor device that converts sound waves into electrical signals.

As shown in FIG. 2A, the example semiconductor structure 200 includes a substrate 202. The substrate 202 supports peripheral portions of the example semiconductor structure 200. For example, the substrate 202 may be located under at least a portion of a sensing portion of the example semiconductor structure 200. Accordingly, the substrate 202 may have a circular shape (e.g., similar to the octagonal shape depicted in FIG. 2B). As used herein, “circular” refers to points on the substrate 202 being approximately equidistant (e.g., within a 5% or 10% margin of error) from a center point. In some implementations, the substrate 202 may comprise a silicon-based material (e.g., a bulk silicon substrate, monocrystalline silicon, p-doped silicon, and/or n-doped silicon, among other examples).

As further shown in FIG. 2A, the example semiconductor structure 200 includes a dielectric region 204. The dielectric region 204 is disposed between the substrate 202 and peripheral portions of the example semiconductor structure 200 (e.g., the sensing portion of the example semiconductor structure 200). Accordingly, the dielectric region 204 may also have a circular shape (e.g., similar to the octagonal shape depicted in FIG. 2B). An outer perimeter of the dielectric region 204 may be aligned with an outer perimeter of the substrate 202. However, an inner perimeter of the dielectric region 204 may overlap an inner perimeter of the substrate 202, or may be laterally offset from the inner perimeter of the substrate 202, as shown in FIG. 2A.

The example semiconductor structure 200 further includes a piezo-membrane 206, divided into a portion 206a arranged to be stationary (and thus forming a “sensing” portion of the example semiconductor structure 200) and a portion 206b arranged to move in response to sound waves (and thus forming a “non-sensing” portion of the example semiconductor structure 200). As shown in FIG. 2A, the piezo-membrane 206 may include three electrodes 208a, 208b, and 208c. Each electrode 208 may include molybdenum (Mo) and/or another type of conductive material. Each electrode 208 may have a thickness in a range from approximately 10 nanometers (nm) to approximately 100 nm. Selecting a thickness of at least 10 nm allows for changes in electrical charge caused by mechanical stress to be measured—a smaller thickness would result in changes in charge that are too small to measure, which degrades performance of a device including the example semiconductor structure 200. Selecting a thickness of no more than 100 nm prevents the electrodes from significantly impacting a tensile strength of the piezo-membrane 206—a larger thickness would affect the tensile strength such that sound waves are inaccurately converted to analog electrical signals. However, other thicknesses are within the scope of the present disclosure. Although the example semiconductor structure 200 is depicted with three electrodes, other examples may include two electrodes. A total thickness of a piezo-membrane with two electrodes may be approximately equal to a total thickness of a piezo-membrane with three electrodes (e.g., by increasing a thickness of each piezo-electric layer 210 accordingly).

As further shown in FIG. 2A, the piezo-membrane 206 may include piezo-electric layers 210a, 210b, 210c, and 210d. Each piezo-electric layer 210 may include an aluminum nitride (AlN) or another type of piezo-electric material (e.g., whether crystalline, ceramic, or polymeric). The top and bottom piezo-electric layers 210a and 210d may each have a thickness in a range from approximately 5 nm to approximately 50 nm. Selecting a thickness of at least 5 nm allows for changes in electrical charge to be caused by mechanical stress—a smaller thickness would result in changes in charge that are too small to measure, which degrades performance of a device including the example semiconductor structure 200. Selecting a thickness of no more than 50 nm allows the piezo-membrane 206 to move in response to sound waves—a larger thickness would result in quieter sounds not moving the piezo-membrane 206. However, other thicknesses are within the scope of the present disclosure. Additionally, the piezo-electric layers 210b and 210c may each have a thickness in a range from approximately 100 nm to approximately 1000 nm. Selecting a thickness of at least 100 nm allows for changes in electrical charge to be caused by mechanical stress—a smaller thickness would result in changes in charge that are too small to measure, which degrades performance of a device including the example semiconductor structure 200. Selecting a thickness of no more than 1000 nm allows the piezo-membrane 206 to move in response to sound waves—a larger thickness would result in quieter sounds not moving the piezo-membrane 206. However, other thicknesses are within the scope of the present disclosure.

In some implementations, as shown in FIG. 2A, the dielectric region 204 may be smaller than the portion 206a of the piezo-membrane 206. Therefore, mechanical stress on the portion 206b may be transferred to the portion 206a for conversion to electrical signals. Additionally, the portion 206b of the piezo-membrane 206 may include an approximate S-shape relative to the portion 206a of the piezo-membrane 206. As used herein, “S-shape” refers to a shape that includes an inflection point (e.g., a shape that switches from positive curvature to negative curvature or from negative curvature to positive curvature). For example, the S-shape may be approximately characterized by a sinusoidal function (e.g., within a 5% or 10% margin of error). Although the S-shape shown in FIG. 2A curves upward relative to the portion 206a of the piezo-membrane 206, other examples may include an S-shape that curves downward relative to the portion 206a of the piezo-membrane 206 (e.g., as described in connection with FIG. 2C). The S-shape reinforces the portion 206b of the piezo-membrane 206 such that an incoming sound wave 212 produces less deflection in the portion 206b. For example, deflection (relative to a horizontal axis) may be less than 8.0 micrometers (μm) at peak. As a result, mismatch between petals of the device including the example semiconductor structure 200 is reduced, as described in connection with FIG. 2B.

Although the electrodes 208a, 208b, and 208c are shown as continuous in FIG. 2A, other examples may include breaks (also referred to as “discontinuities”) in the electrodes 208a, 208b, and 208c. In particular, as described in connection with FIG. 2C, the electrodes 208a, 208b, and 208c may be broken between the portion 206a and the portion 206b of the piezo-membrane 206. As a result, the portions 206a and 206b exhibit similar tensile strength but only the portion 206a is used to generate electrical signals based on mechanical stress.

As shown in FIG. 2A, the electrodes 208a, 208b, and 208c may connect to contacts 214a, 214b, and 214c, respectively. Each contact 214 may include copper (Cu) and/or another type of conductive material. The contacts 214a, 214b, and 214c may connect the example semiconductor structure 200 to a back-end-of-line (BEOL) metallization stack (not shown). The BEOL metallization stack may electrically connect the device including the example semiconductor structure 200 to control circuitry that may be used to convert analog electrical signals from the piezo-membrane 206 into digital electrical signals (e.g., for storage and/or transmission).

FIG. 2B illustrates a top-down view of the example semiconductor structure 200. The piezo-membrane is thus divided into eight petals (labeled 216a, 216b, 216c, 216d, 216e, 216f, 216g, and 216h in FIG. 2B). Therefore, each petal 216 may independently generate an electrical signal based on mechanical stress caused by a sound wave. Because each petal 216 includes an approximate S-shape, as described in connection with FIG. 2A, a mismatch between displacements of the petals may be in a range from 0.0 μm to approximately 5.0 μm. Other examples may include mismatch that is slightly greater but still below 6 μm. By maintaining mismatch below 6 μm, fewer incoming sound waves leak through a gap between the petals, and performance of a device including the example semiconductor structure 200 is increased. Additionally, the gap between the petals is less likely to allow dust and other small particles to enter the device, which further improves performance of the device.

As further shown in FIG. 2B, a first point (e.g., represented by a) may be located closer to a center of the example semiconductor structure 200 as compared with a second point (e.g., represented by b). Because of the approximate S-shape, a lower portion of the piezo-membrane at the first point a may be at least 1 μm above the lower portion of the piezo-membrane at the second point b (e.g., when the S-shape curves upward, as described in connection with FIG. 2B). Alternatively, a lower portion of the piezo-membrane at the first point a may be at least 1 μm below the lower portion of the piezo-membrane at the second point b (e.g., when the S-shape curves downward, as described in connection with FIG. 2B). Selecting a curvature that results in at least a 1 μm difference (e.g., between peak and trough of the lower portion of the piezo-membrane) allows for the sufficient reinforcement of the piezo-membrane to maintain a mismatch below 6 μm—selecting a curvature that results in a smaller difference would allow for larger mismatches that reduce performance.

FIG. 2C is a diagram of an example semiconductor structure 250 described herein. In particular, FIG. 2C illustrates a cross-section view of the example semiconductor structure 250. The example semiconductor structure 250 may be included in a MEMS microphone (e.g., a piezo-electric-based MEMS microphone) and/or another type of semiconductor device that converts sound waves into electrical signals.

The example semiconductor structure 250 is similar to the example semiconductor structure 200 but includes the dielectric region 204 as flush with the substrate 202. Additionally, the electrodes 208a, 208b, and 208c are broken between a sensing portion 206a of the example semiconductor structure 250 and a non-sensing portion 206b of the example semiconductor structure 250. The piezo-electric layers 210 are continuous through the breaks.

As further shown in FIG. 2C, the approximate S-shape in the non-sensing portion 206b includes a plurality of inflection points. Therefore, the approximate S-shape shown in FIG. 2C may also be referred to as a “corrugated pattern.” A lower portion of the piezo-membrane at a set of first points may be a distance (e.g., represented by d) below the lower portion of the piezo-membrane at a set of second points. The distance d may be at least 1 μm, similarly as described in connection with FIG. 2B. Selecting a curvature that results in at least a 1 μm difference (e.g., between peaks and troughs of the lower portion of the piezo-membrane) allows for the sufficient reinforcement of the piezo-membrane to maintain a mismatch below 6 μm—selecting a curvature that results in a smaller difference would allow for larger mismatches that reduce performance.

As indicated above, FIGS. 2A-2C are provided as examples. Other examples may differ from what is described with regard to FIGS. 2A-2C. For example, other examples may include a piezo-membrane that bends downward, as described in connection with FIG. 2C, and includes a single approximate S-shape, as described in connection with FIG. 2A.

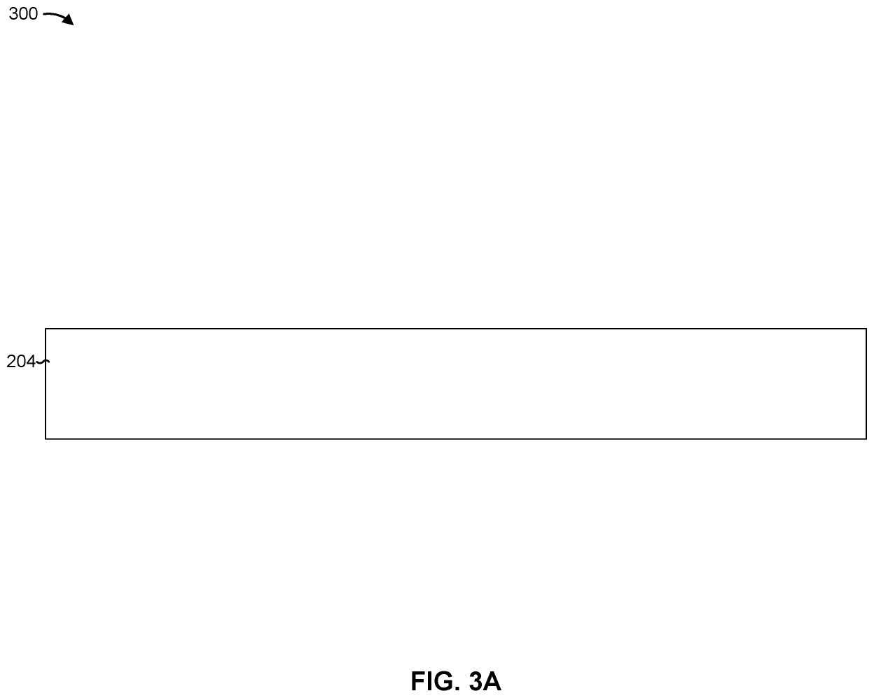

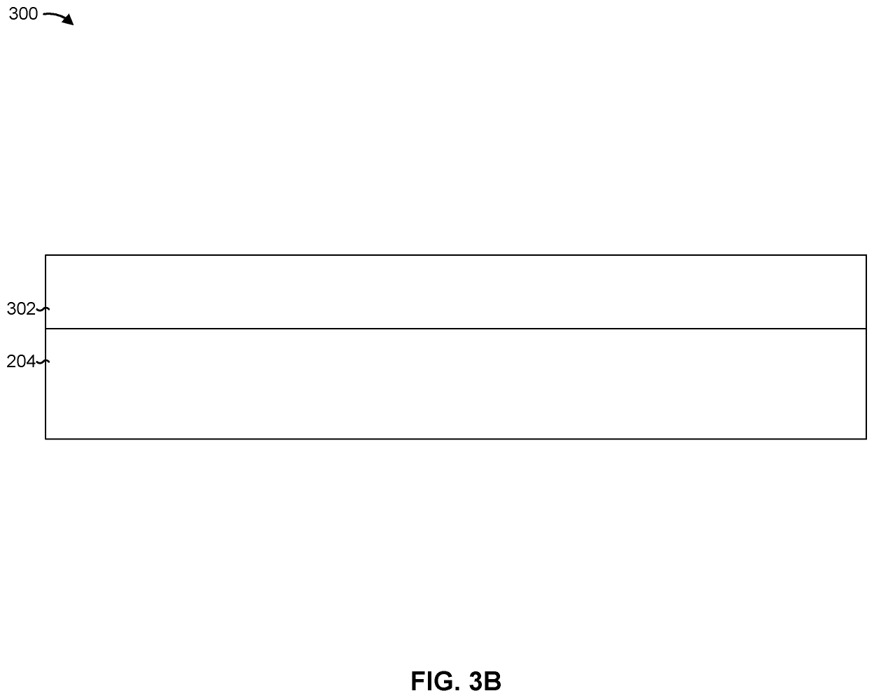

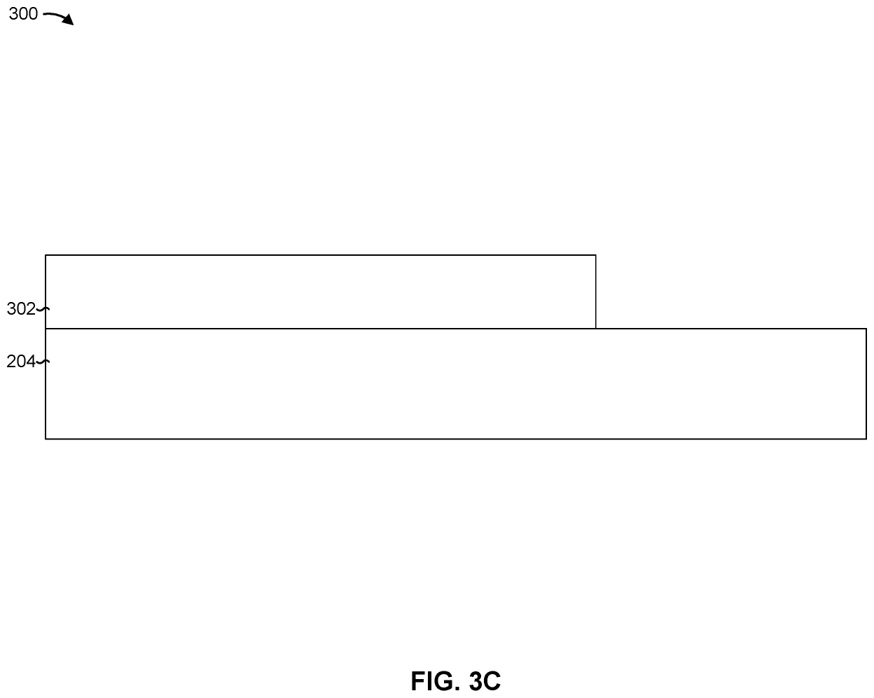

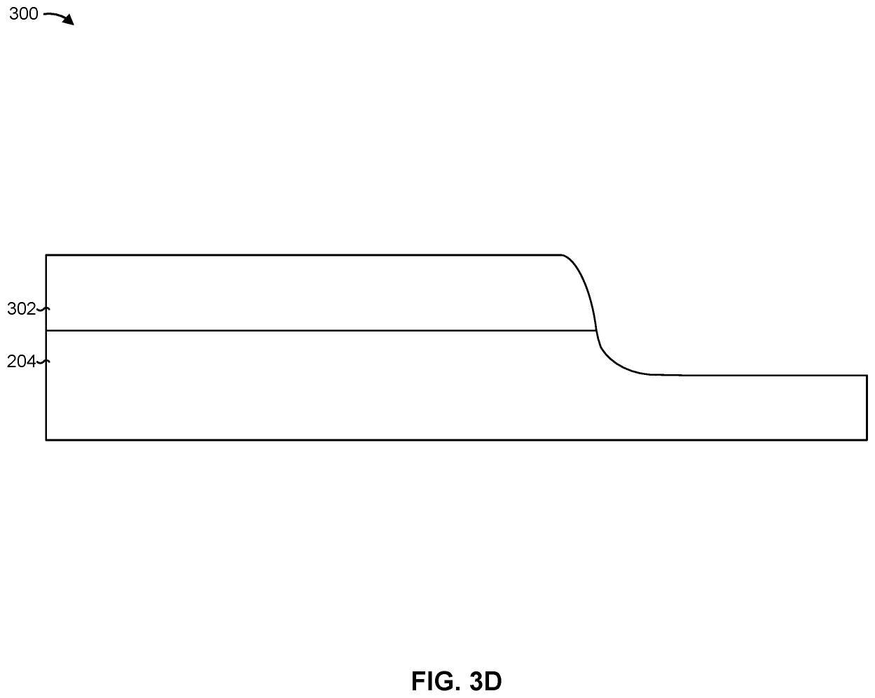

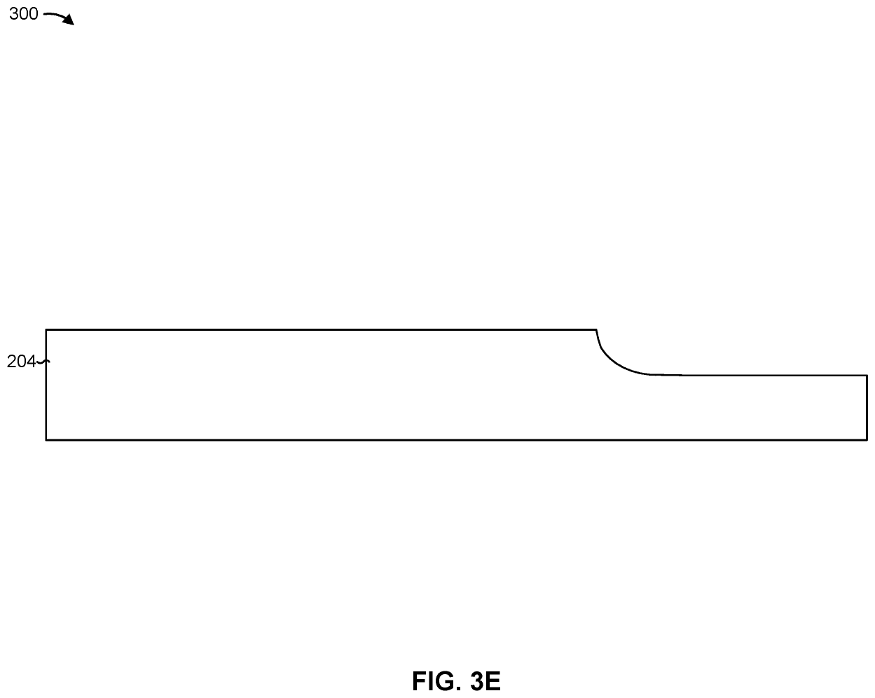

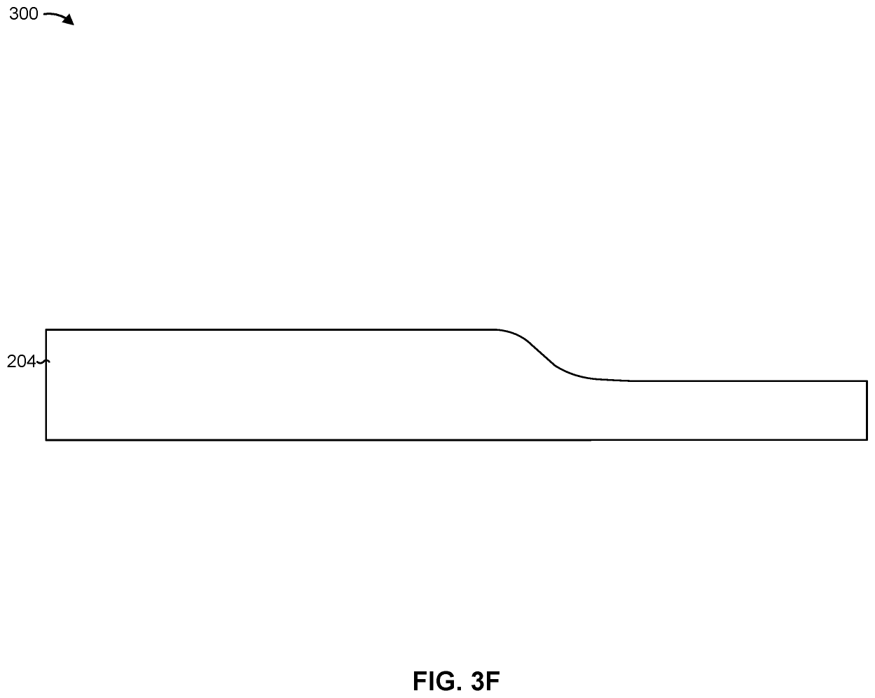

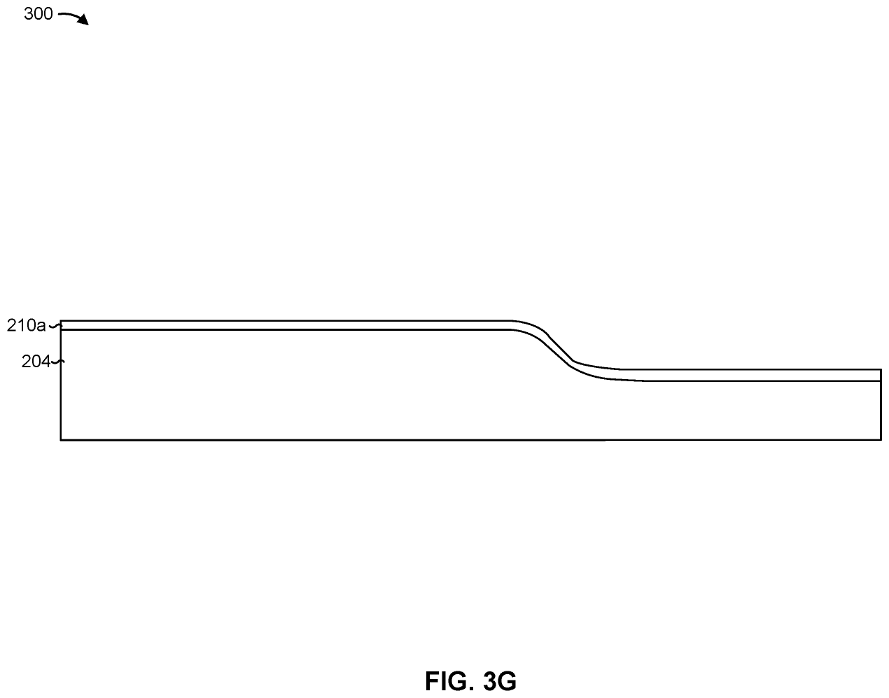

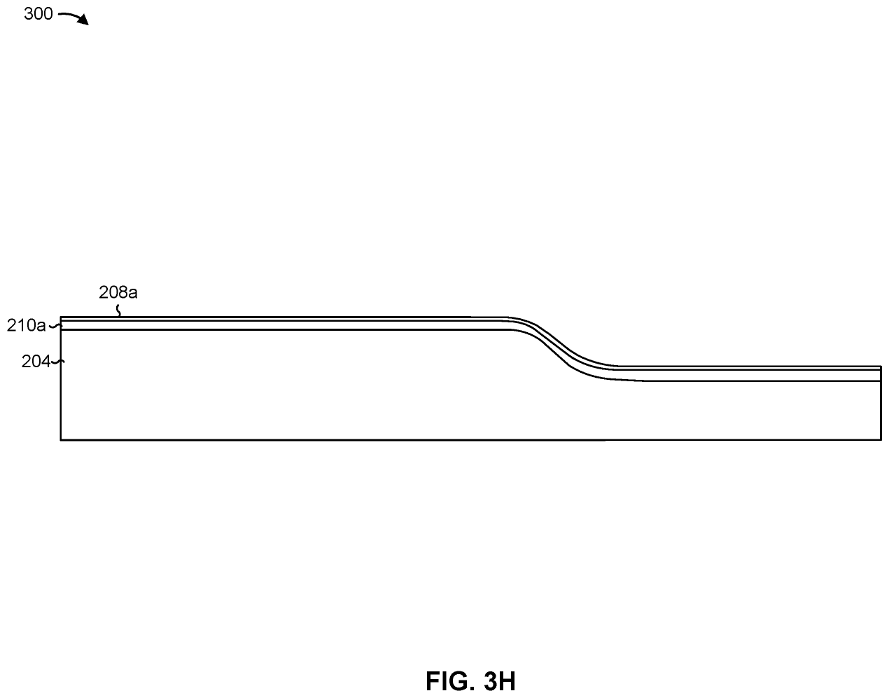

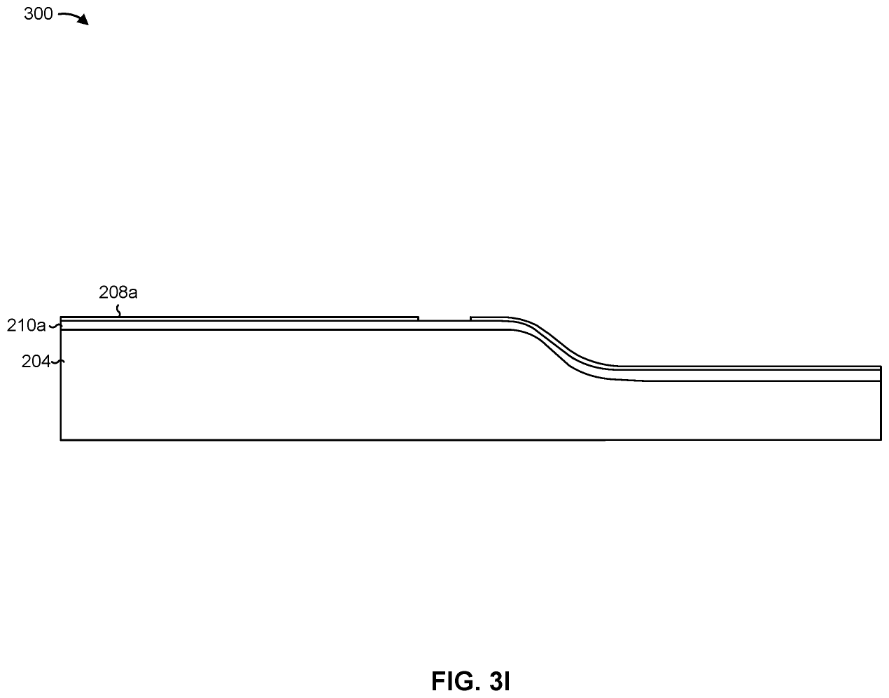

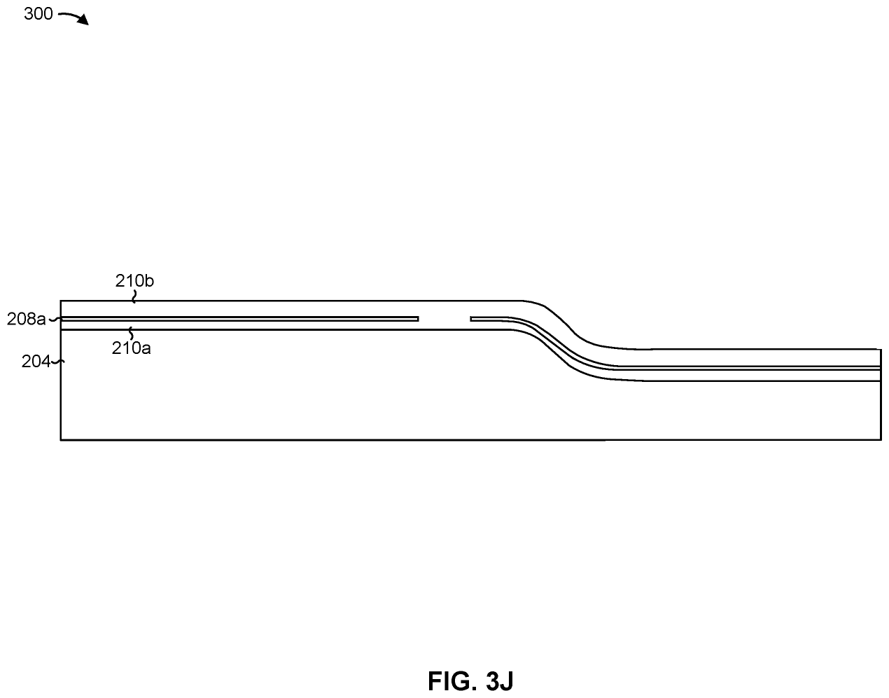

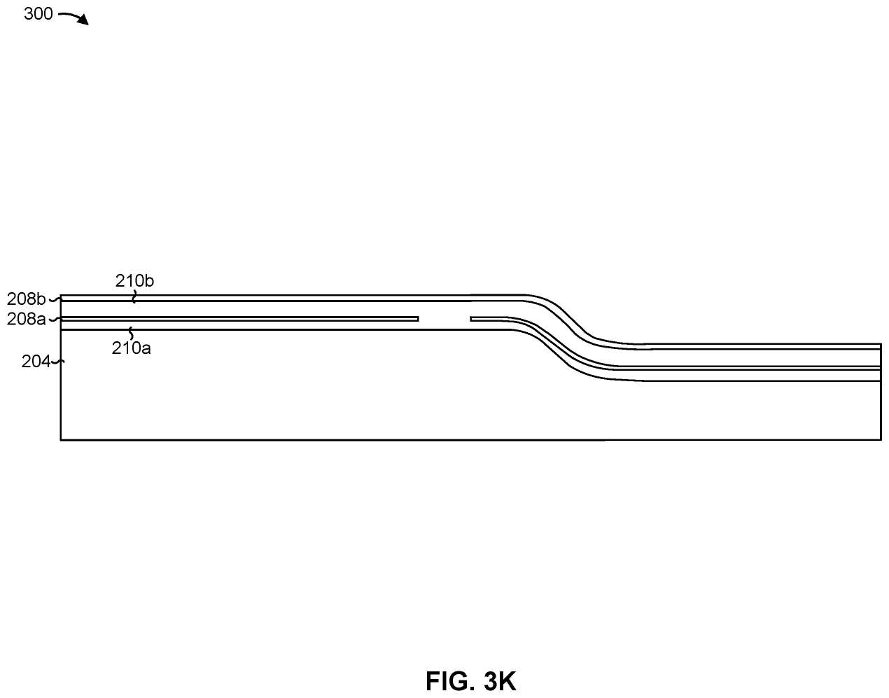

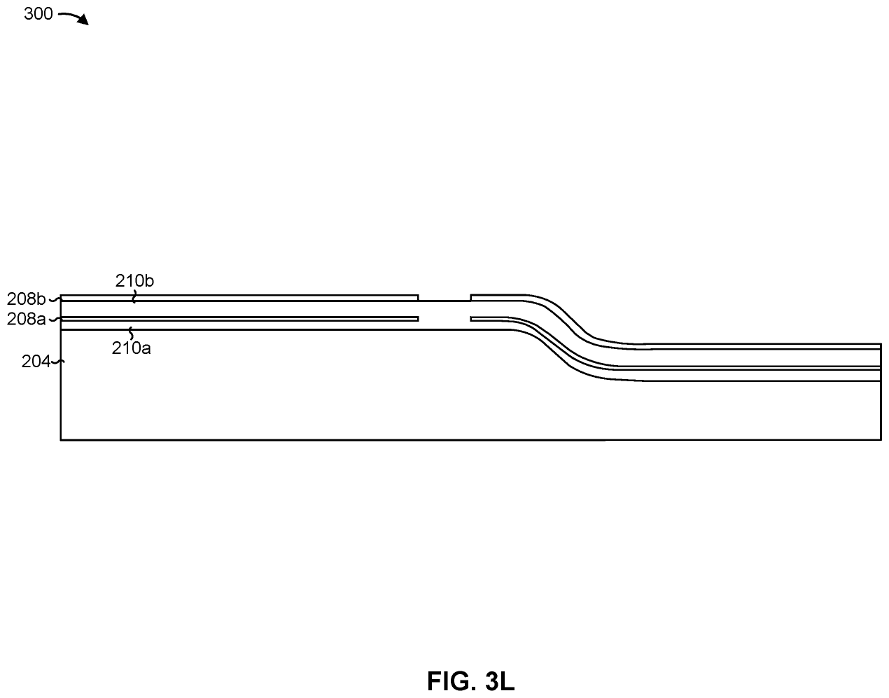

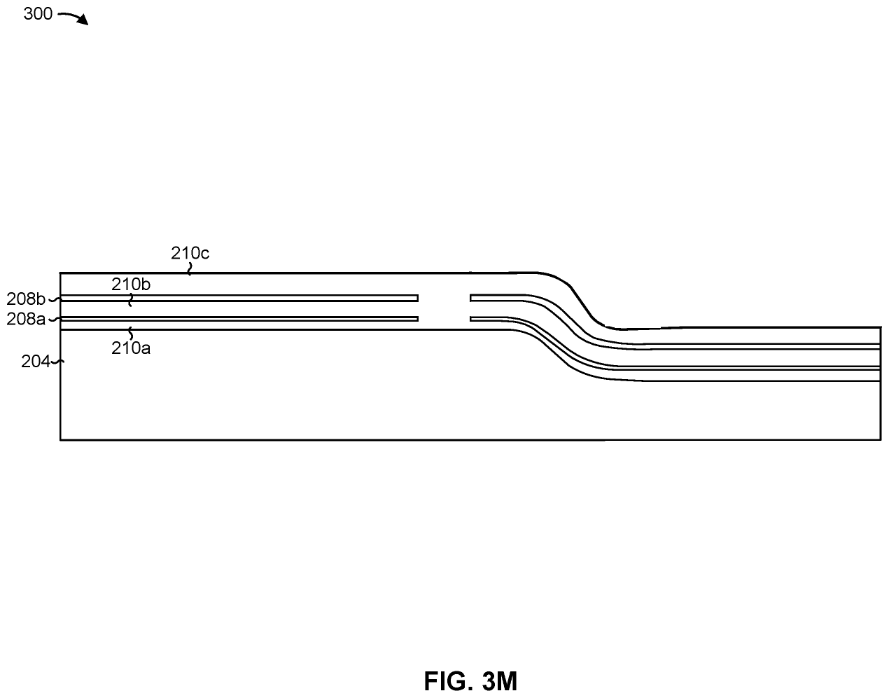

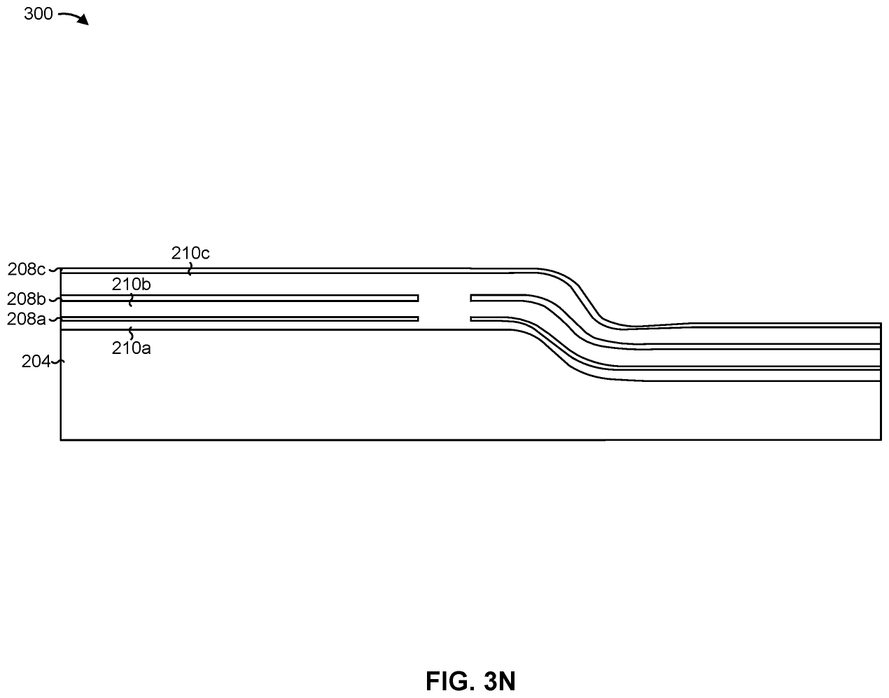

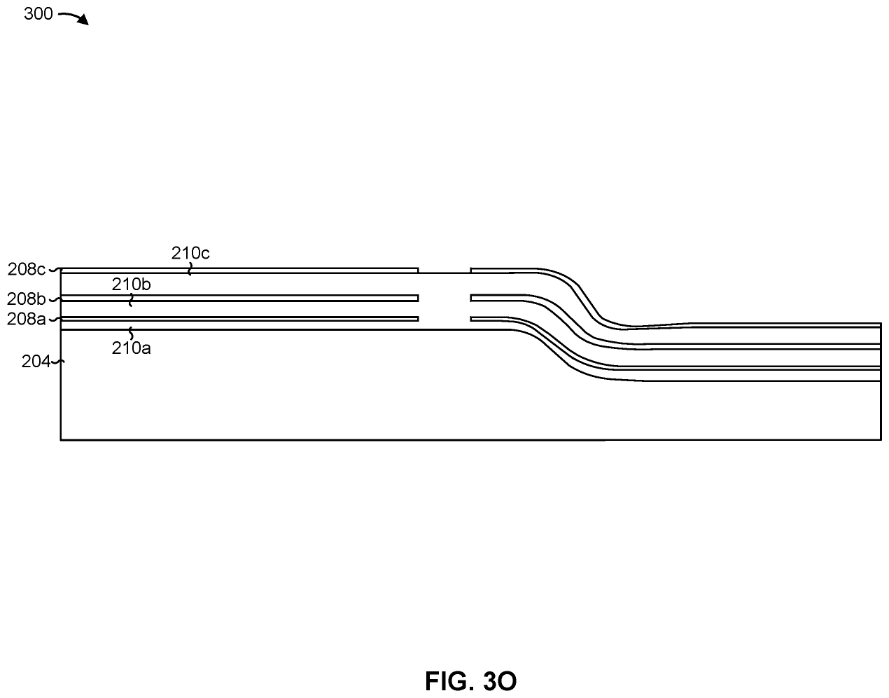

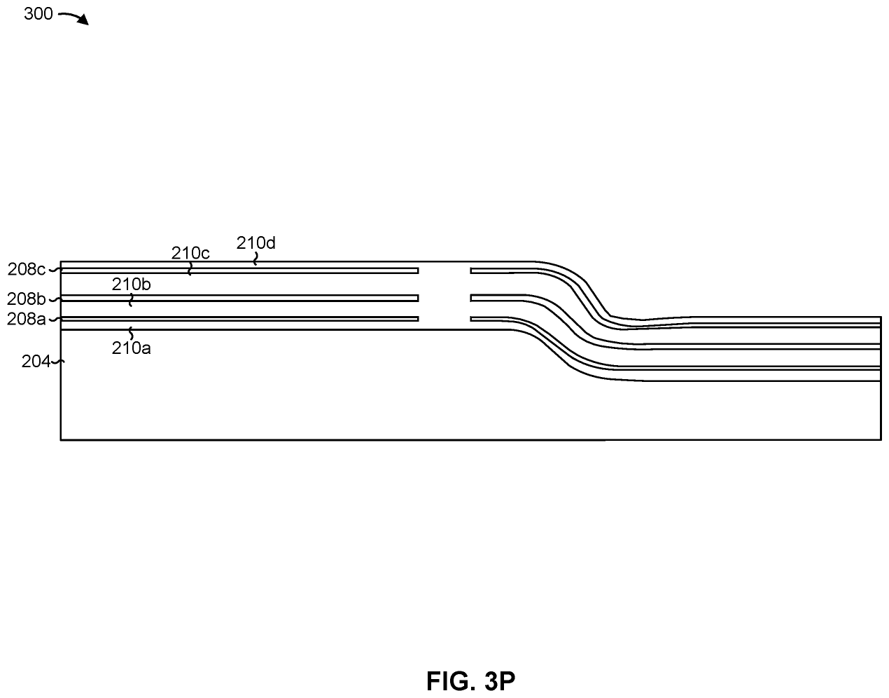

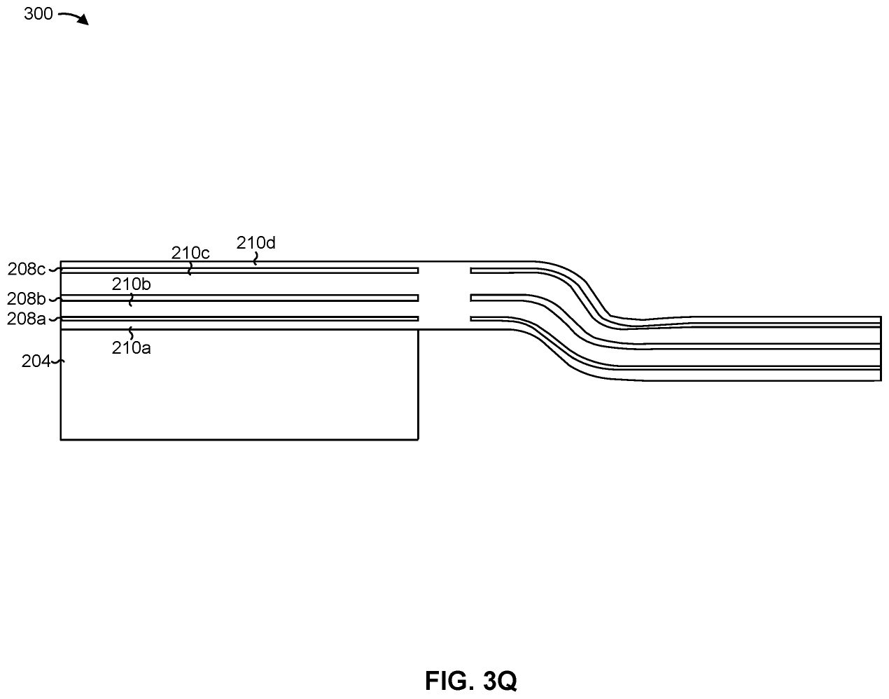

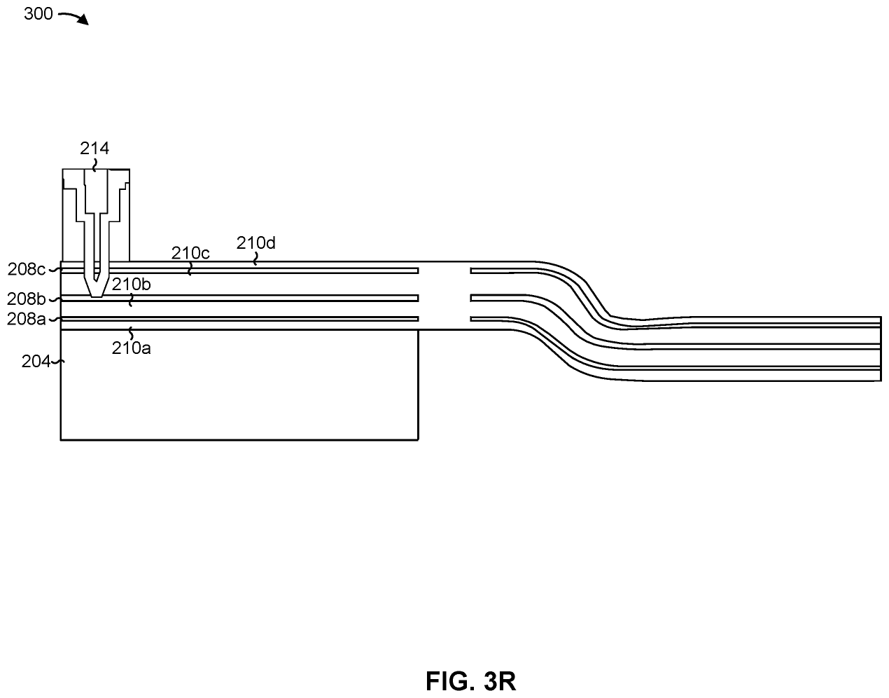

FIGS. 3A-3R are diagrams of an example implementation 300 described herein. The example implementation 300 may be an example process or method for forming the example semiconductor structure 200. The example implementation 300 may include a lithography technique for forming an approximate S-shape to reinforce a piezo-membrane of the example semiconductor structure 200.

As shown in FIG. 3A, the example process for forming the semiconductor structure may be performed in connection with a dielectric region 204. As described above, the dielectric region 204 may include an oxide material and/or another type of dielectric material.

As shown in FIG. 3B, the example process may be performed in connection with a mask 302, among other examples. For example, a deposition tool 102 may form the mask 302 over and/or on the frontside surface of the dielectric region 204. In some implementations, a deposition tool 102 forms the mask 302 using a spin-coating technique, a CVD technique, a PVD technique, an ALD technique, and/or another deposition technique.

As shown in FIG. 3C, the mask 302 may be patterned. In some implementations, an exposure tool 104 exposes the mask 302 to a radiation source to form a pattern on the mask 302, and a developer tool 106 develops and removes portions of the mask 302 to expose the pattern. Although the example implementation 300 is described in connection with a single masking layer, other examples may include a plurality of masking layers (e.g., a combination of a photoresist layer and a hardmask layer and/or a combination of a bottom layer (BL), a middle layer (ML), and a photoresist (PR) layer).

As shown in FIG. 3D, the dielectric layer 204 may be etched. For example, an etch tool 108 may etch a portion of the dielectric layer 204. In some implementations, an etch tool 108 uses a wet etch technique, a dry etch technique, a plasma-enhanced etch technique, and/or another type of etch technique to etch the portion of the dielectric layer 204. The dielectric layer 204 may be patterned using the mask 302, which results in curvature near an edge of the mask 302.

As shown in FIG. 3E, the mask 302 may be removed. For example, a photoresist removal tool 114 may remove remaining portions of the mask 302 (e.g., using a chemical stripper, a plasma asher, and/or another technique) after an etch tool 108 etches the dielectric layer 204.

As shown in FIG. 3F, the dielectric layer 204 may be etched again. For example, an etch tool 108 may etch an additional portion of the dielectric layer 204. In some implementations, an etch tool 108 uses a wet etch technique, a dry etch technique, a plasma-enhanced etch technique, and/or another type of etch technique to etch the additional portion of the dielectric layer 204. The dielectric layer 204 may be patterned without the mask 302, which results in an inflection point in the dielectric layer 204.

As shown in FIG. 3G, a piezo-electric layer 210a may be formed. For example, a deposition tool 102 may form the piezo-electric layer 210a over and/or on the frontside surface of the dielectric layer 204. In some implementations, a deposition tool 102 forms the piezo-electric layer 210a using a spin-coating technique, a CVD technique, a PVD technique, an ALD technique, and/or another deposition technique.

As shown in FIG. 3H, a bottom electrode 208a may be formed. For example, a deposition tool 102 may form the bottom electrode 208a over and/or on a frontside surface of the piezo-electric layer 210a. In some implementations, a deposition tool 102 forms the bottom electrode 208a using a spin-coating technique, a CVD technique, a PVD technique, an ALD technique, and/or another deposition technique.

As shown in FIG. 3I, a break is formed in the bottom electrode 208a. The break may separate a non-sensing portion (e.g., a portion including the inflection point and curving downward in the example implementation 300) from a sensing portion. In some implementations, a deposition tool 102 may form a photoresist layer over and/or on the frontside surface of the bottom electrode 208a, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch (e.g., use a wet etch technique, a dry etch technique, a plasma-enhanced etch technique, and/or another type of etch technique) the break in the bottom electrode 208a. Accordingly, a surface of the piezo-electric layer 210a may be exposed at the break. A photoresist removal tool 114 may remove remaining portions of the photoresist layer (e.g., using a chemical stripper, a plasma asher, and/or another technique) after the break is formed. In some implementations, the exposed surface of the piezo-electric layer 210a at the break may be cleaned (e.g., using plasma) to reduce oxidation of the piezo-electric layer 210a at the break.

As shown in FIG. 3J, a piezo-electric layer 210b may be formed. For example, a deposition tool 102 may form the piezo-electric layer 210b over and/or on the frontside surface of the bottom electrode 208a. In some implementations, a deposition tool 102 forms the piezo-electric layer 210b using a spin-coating technique, a CVD technique, a PVD technique, an ALD technique, and/or another deposition technique. Because of the break in the bottom electrode 208a, the piezo-electric layers 210a and 210b may contact each other at the break. For example, the piezo-electric layers 210a and 210b may include crystalline layers that are continuous (or at least interface with each other) at the break.

As shown in FIG. 3K, a middle electrode 208b may be formed. For example, a deposition tool 102 may form the middle electrode 208b over and/or on a frontside surface of the piezo-electric layer 210b. In some implementations, a deposition tool 102 forms the middle electrode 208b using a spin-coating technique, a CVD technique, a PVD technique, an ALD technique, and/or another deposition technique.

As shown in FIG. 3L, a break is formed in the middle electrode 208b. The break may separate the non-sensing portion (e.g., the portion including the inflection point and curving downward in the example implementation 300) from the sensing portion. In some implementations, a deposition tool 102 may form a photoresist layer over and/or on the frontside surface of the middle electrode 208b, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch (e.g., use a wet etch technique, a dry etch technique, a plasma-enhanced etch technique, and/or another type of etch technique) the break in the middle electrode 208b. Accordingly, a surface of the piezo-electric layer 210b may be exposed at the break. A photoresist removal tool 114 may remove remaining portions of the photoresist layer (e.g., using a chemical stripper, a plasma asher, and/or another technique) after the break is formed. In some implementations, the exposed surface of the piezo-electric layer 210b at the break may be cleaned (e.g., using plasma) to reduce oxidation of the piezo-electric layer 210b at the break.

As shown in FIG. 3M, a piezo-electric layer 210c may be formed. For example, a deposition tool 102 may form the piezo-electric layer 210c over and/or on the frontside surface of the middle electrode 208b. In some implementations, a deposition tool 102 forms the piezo-electric layer 210c using a spin-coating technique, a CVD technique, a PVD technique, an ALD technique, and/or another deposition technique. Because of the break in the middle electrode 208b, the piezo-electric layers 210b and 210c may contact each other at the break. For example, the piezo-electric layers 210b and 210c may include crystalline layers that are continuous (or at least interface with each other) at the break.

Although the electrode 208b is described as a middle electrode in the example implementation 300, other examples may include only two electrodes such that the electrode 208b functions as a top electrode. Therefore, operations described in connection with FIGS. 3N-3P may be omitted.

As shown in FIG. 3N, a top electrode 208c may be formed. For example, a deposition tool 102 may form the top electrode 208c over and/or on a frontside surface of the piezo-electric layer 210c. In some implementations, a deposition tool 102 forms the top electrode 208c using a spin-coating technique, a CVD technique, a PVD technique, an ALD technique, and/or another deposition technique.

As shown in FIG. 3O, a break is formed in the top electrode 208c. The break may separate the non-sensing portion (e.g., the portion including the inflection point and curving downward in the example implementation 300) from the sensing portion. In some implementations, a deposition tool 102 may form a photoresist layer over and/or on the frontside surface of the top electrode 208c, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch (e.g., use a wet etch technique, a dry etch technique, a plasma-enhanced etch technique, and/or another type of etch technique) the break in the top electrode 208c. Accordingly, a surface of the piezo-electric layer 210c may be exposed at the break. A photoresist removal tool 114 may remove remaining portions of the photoresist layer (e.g., using a chemical stripper, a plasma asher, and/or another technique) after the break is formed. In some implementations, the exposed surface of the piezo-electric layer 210c at the break may be cleaned (e.g., using plasma) to reduce oxidation of the piezo-electric layer 210c at the break.

As shown in FIG. 3P, a piezo-electric layer 210d may be formed. For example, a deposition tool 102 may form the piezo-electric layer 210d over and/or on the frontside surface of the top electrode 208c. In some implementations, a deposition tool 102 forms the piezo-electric layer 210d using a spin-coating technique, a CVD technique, a PVD technique, an ALD technique, and/or another deposition technique. Because of the break in the top electrode 208c, the piezo-electric layers 210c and 210d may contact each other at the break. For example, the piezo-electric layers 210c and 210d may include crystalline layers that are continuous (or at least interface with each other) at the break.

As shown in FIG. 3Q, the dielectric layer 204 may be removed from under a portion of a piezo-electric membrane (e.g., formed by the stack of electrodes 208a, 208b, and 208c and piezo-electric layers 210a, 210b, 210c, and 210d). For example, an etch tool 108 may etch the portion of the dielectric layer 204 under the non-sensing portion. In some implementations, an etch tool 108 uses a wet etch technique, a dry etch technique, a plasma-enhanced etch technique, and/or another type of etch technique to etch the portion of the dielectric layer 204. Conformal deposition of the electrodes 208a, 208b, and 208c and the piezo-electric layers 210a, 210b, 210c, and 210d results in a semiconductor stack that still retains the approximate S-shape patterned into the dielectric layer 204. Therefore, as shown in FIG. 3Q, the non-sensing portion of the semiconductor structure curves downward relative to the sensing portion.

As shown in FIG. 3R, a contact 214 may be formed to contact the electrode layer 208b in the semiconductor stack. The contact 214 may be formed in the sensing portion of the semiconductor structure (that is, a portion of the piezo-electric membrane configured to be stationary). For example, an etch tool 108 may etch the portion of the semiconductor stack in the sensing portion. In some implementations, an etch tool 108 uses a wet etch technique, a dry etch technique, a plasma-enhanced etch technique, and/or another type of etch technique to etch the portion of the semiconductor stack. A deposition tool 102 may form the contact 214. Although the example implementation 300 depicts one contact, other contacts may be formed at different parts of the sensing portion of the semiconductor structure (e.g., at different petals, as described below).

Additionally, the semiconductor structure may be cut into a plurality of petals (e.g., as described in connection with FIG. 2B). For example, from a top-down view, a singulation tool 116 may cut the piezo-membrane into the plurality of petals. A singulation tool 116 may dice or otherwise separate the plurality of petals from each other. Alternatively, an etch tool 108 may use a wet etch technique, a dry etch technique, a plasma-enhanced etch technique, and/or another type of etch technique to separate the plurality of petals from each other.

As indicated above, FIGS. 3A-3R are provided as an example. Other examples may differ from what is described with regard to FIGS. 3A-3R. For example, the dielectric layer 204 may be supported by a substrate 202, as described in connection with FIGS. 2A and 2C. The substrate 202 may be formed after operations described in connection with FIGS. 3A-3R. Alternatively, the dielectric layer 204 may be formed on the substrate 202 such that a portion of the substrate 202 is removed from under the portion of the semiconductor stack that is configured to move in response to sound waves (e.g., similarly as described in connection with FIG. 3Q).

Additionally, or alternatively, the mask 302 may be patterned such that a plurality of curvatures are formed in the dielectric layer 204 during a first etch process (e.g., as described in connection with FIG. 3D). Therefore, a plurality of inflection points are formed in the dielectric layer 204 during a second etch process (e.g., as described in connection with FIG. 3F).

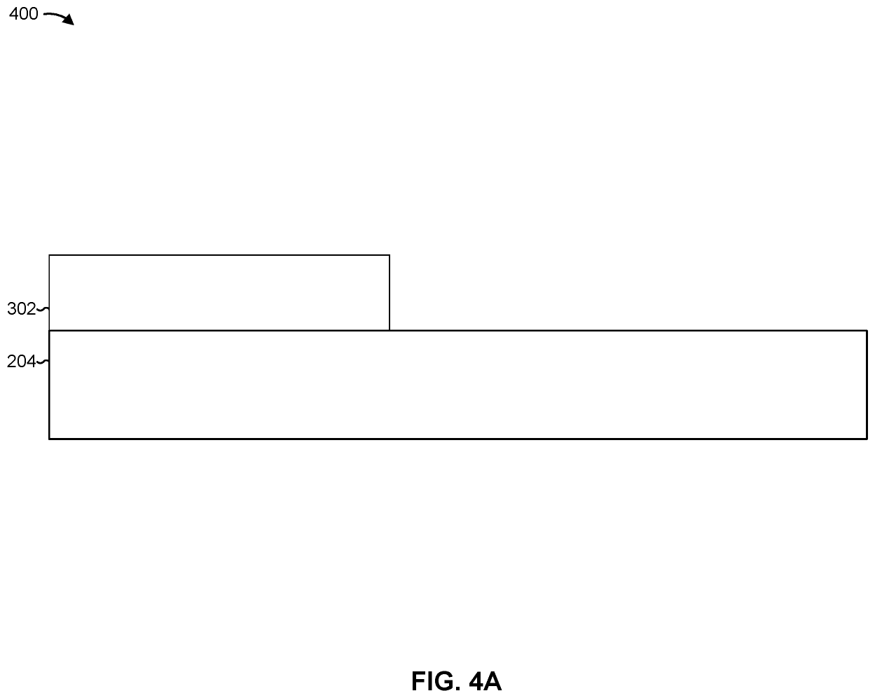

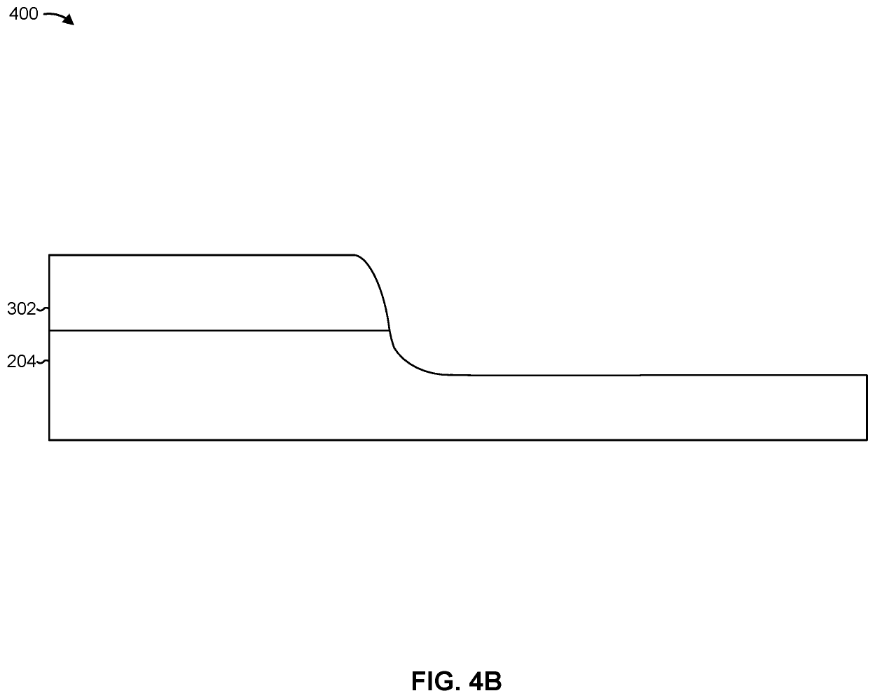

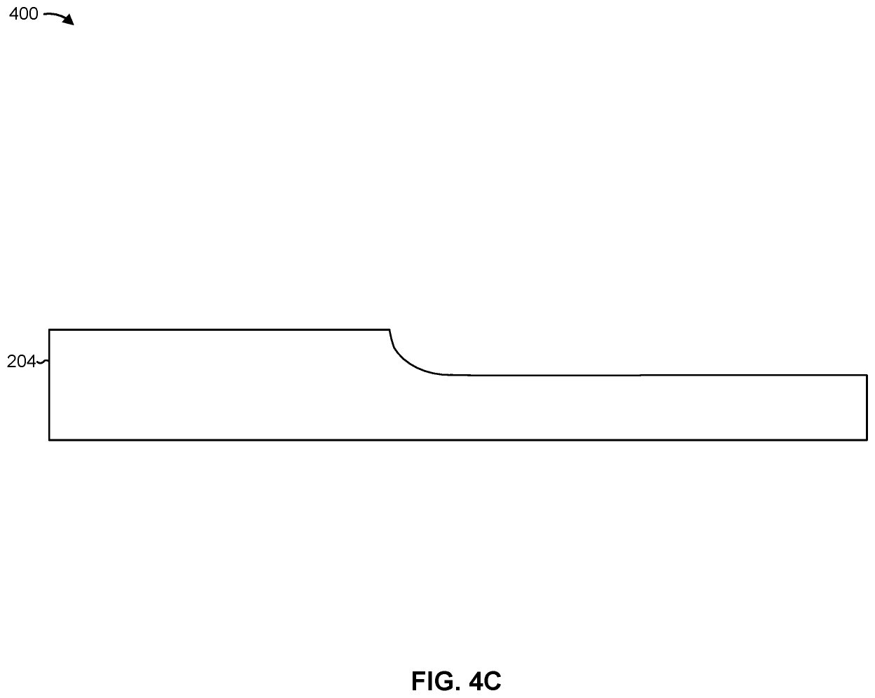

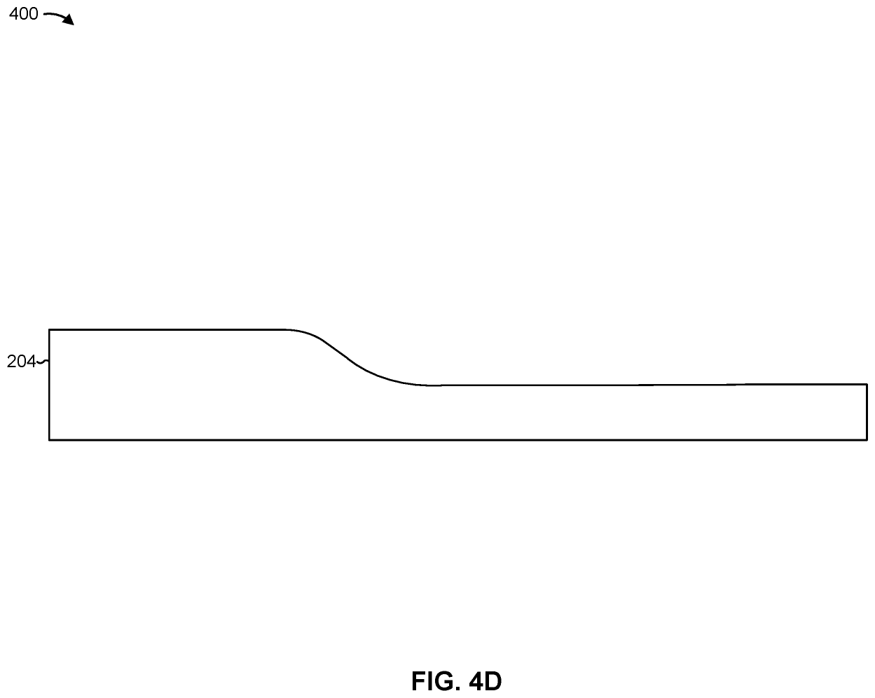

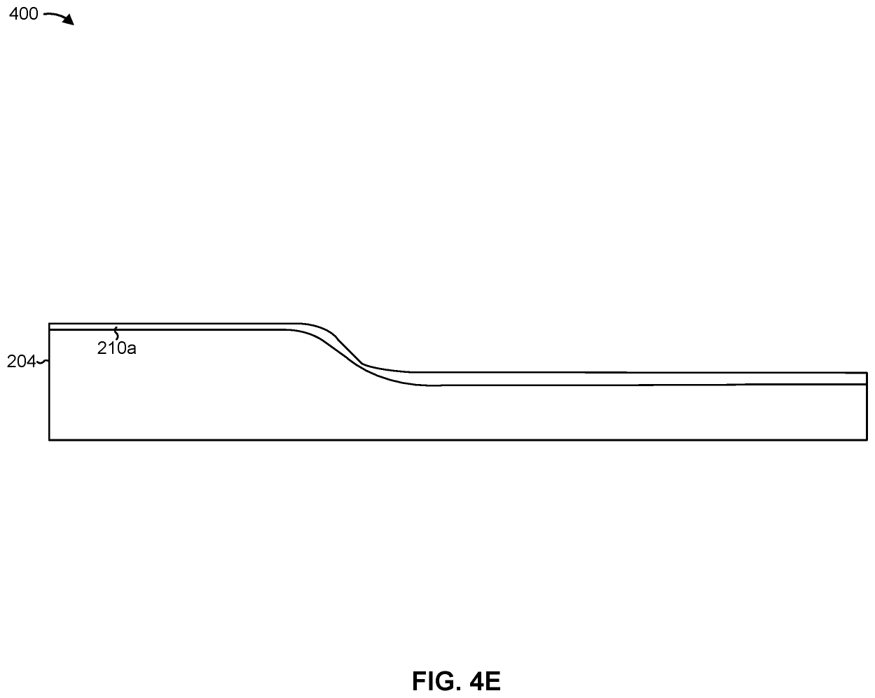

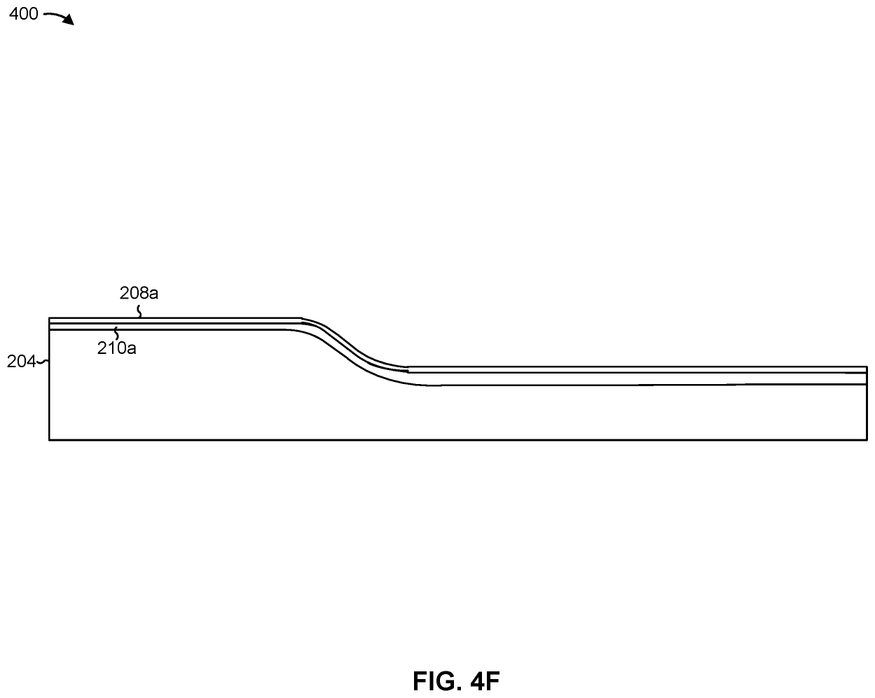

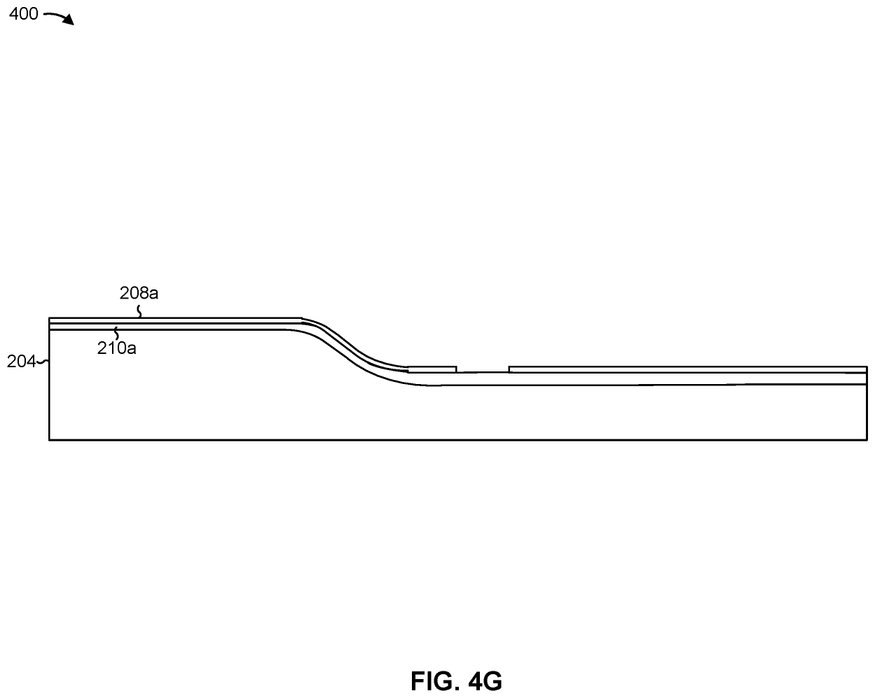

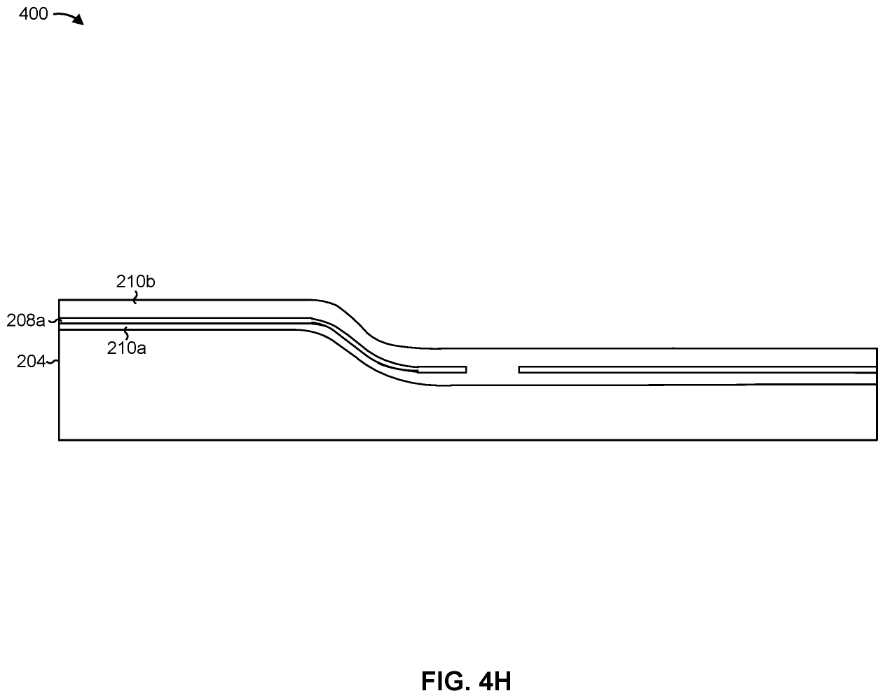

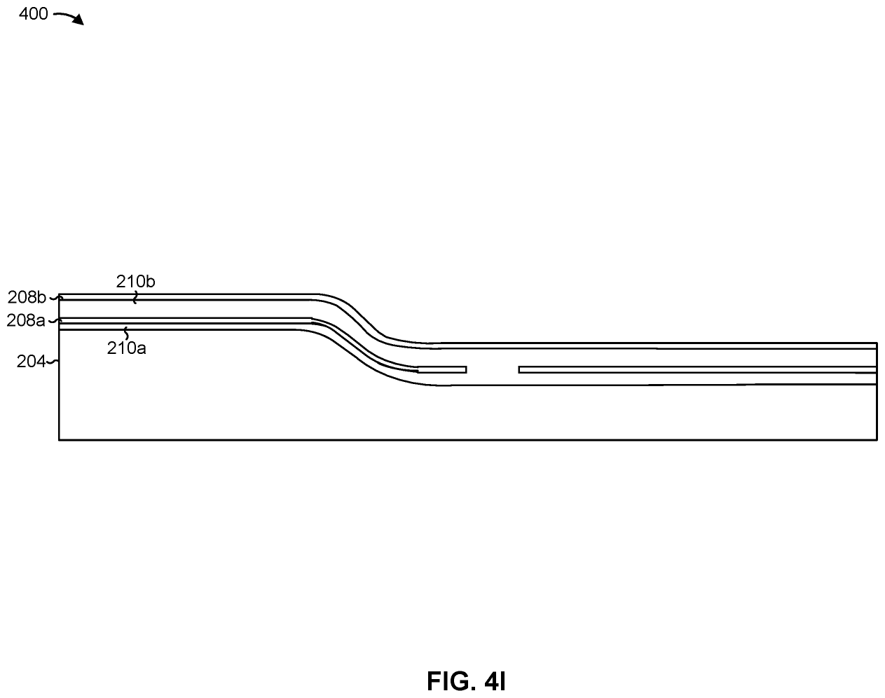

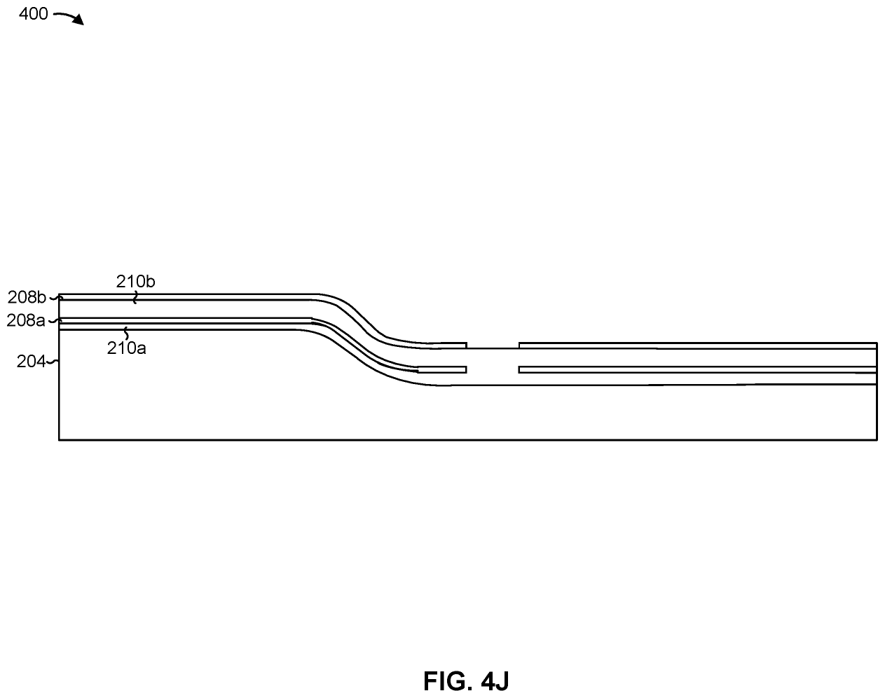

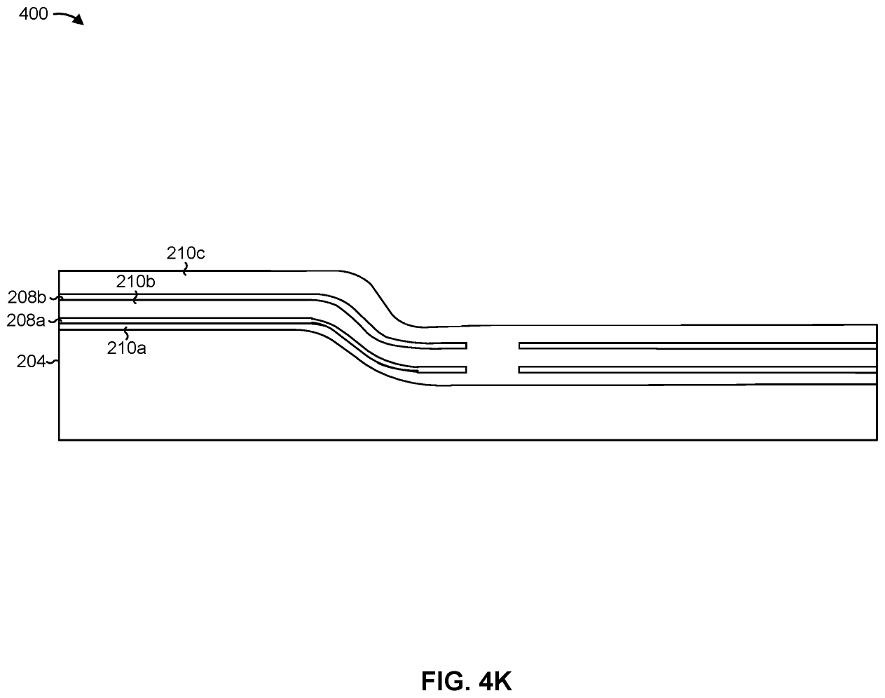

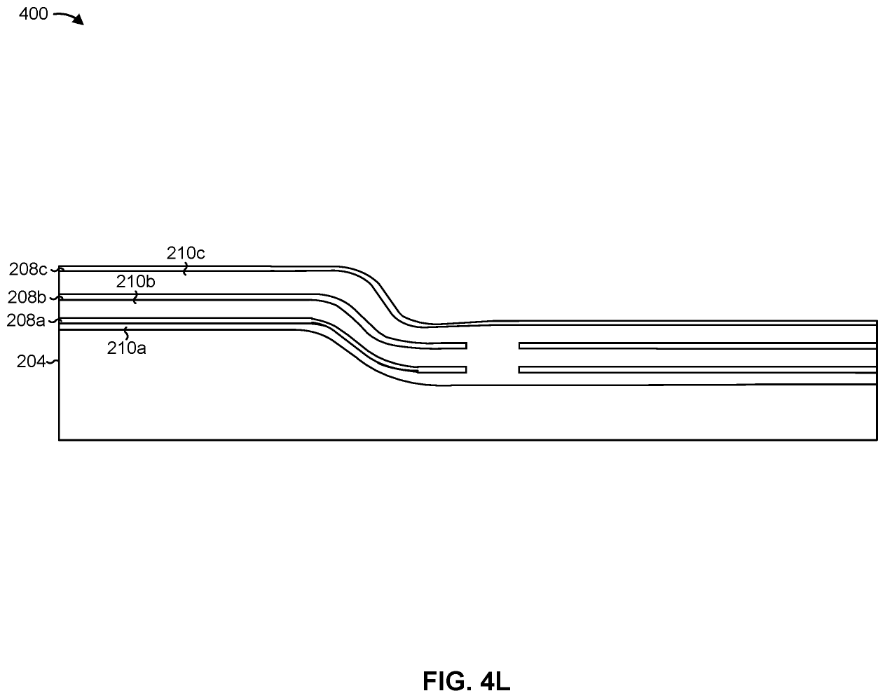

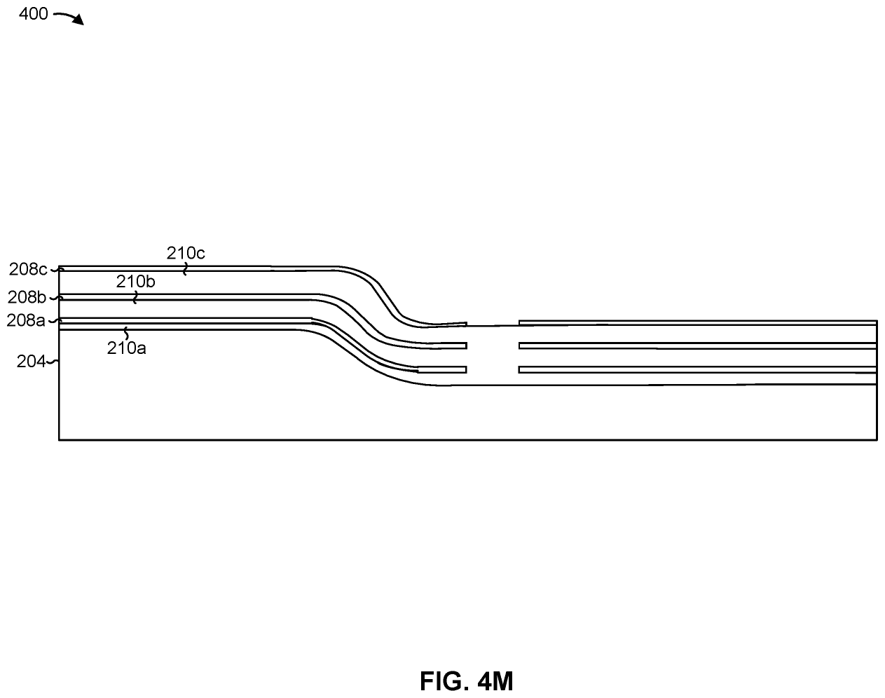

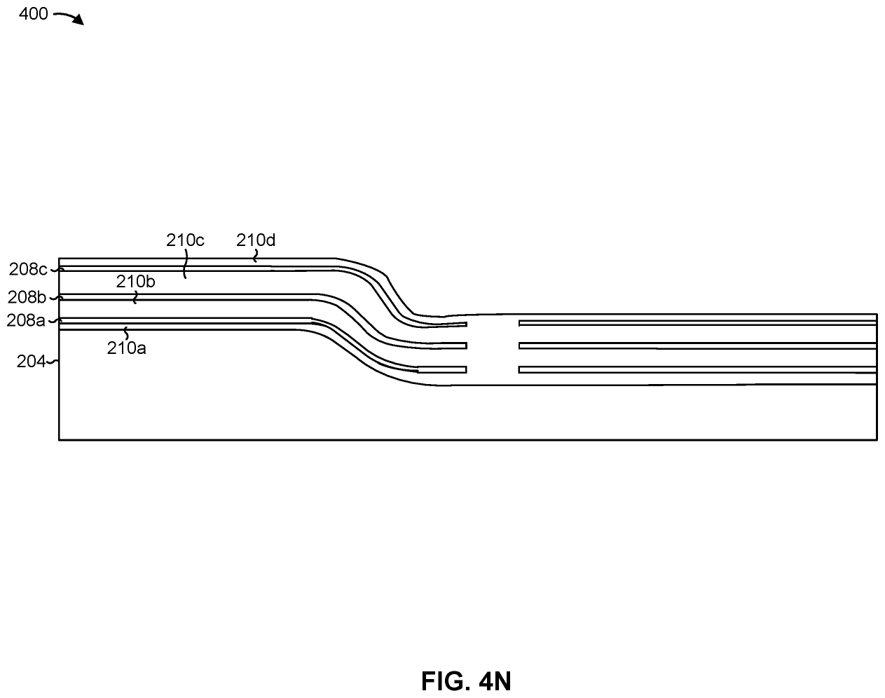

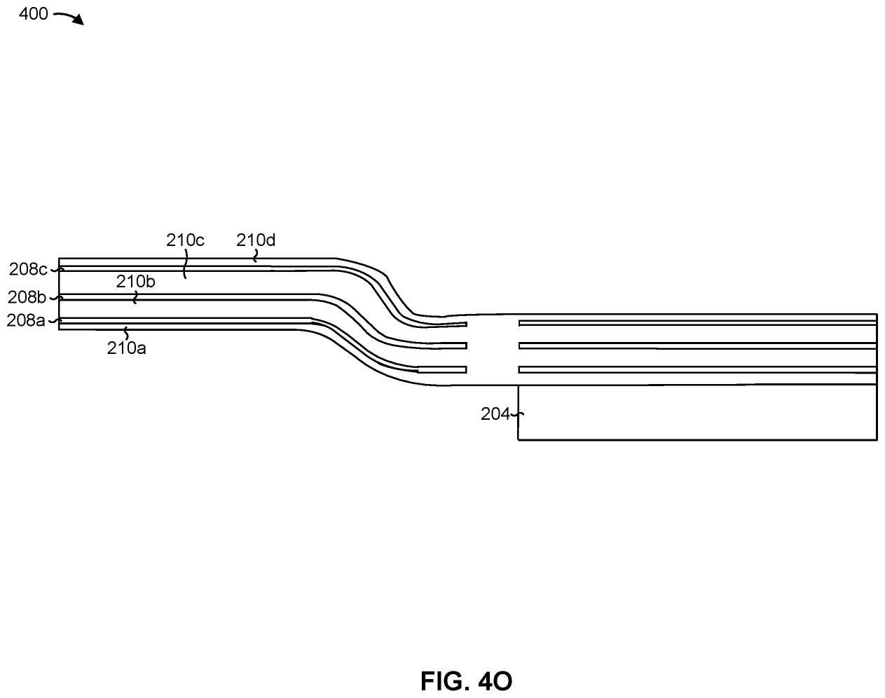

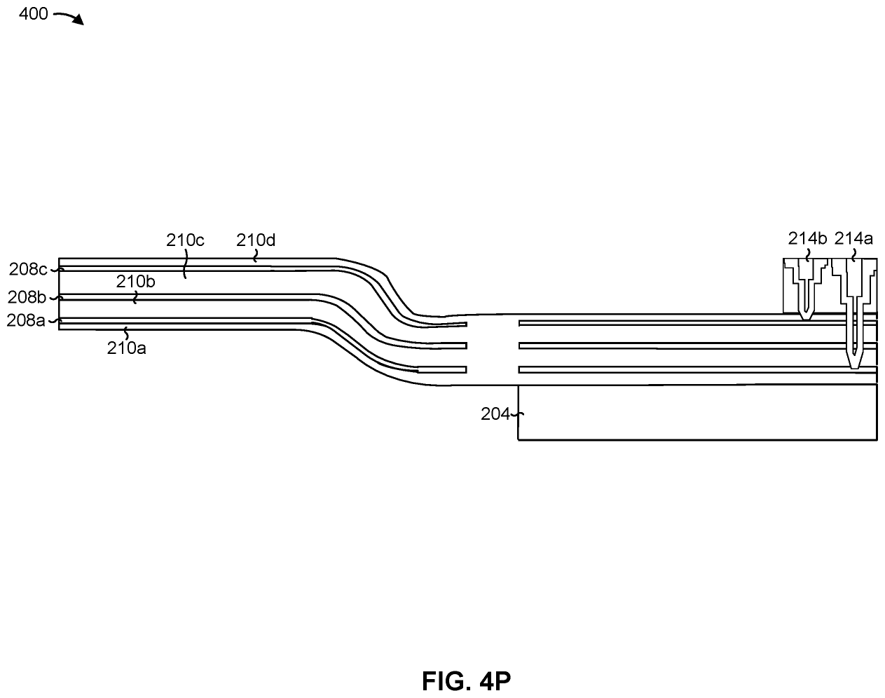

FIGS. 4A-4P are diagrams of an example implementation 400 described herein. The example implementation 400 may be an example process or method for forming the example semiconductor structure 200. The example implementation 400 may include a lithography technique for forming an approximate S-shape to reinforce a piezo-membrane of the example semiconductor structure 200.

As shown in FIG. 4A, the example process for forming the semiconductor structure may be performed in connection with a dielectric region 204 and a mask 302 (e.g., formed as described in connection with FIG. 3B). Additionally, as further shown in FIG. 4A, the mask 302 may be patterned (e.g., as described in connection with FIG. 3C).

As shown in FIG. 4B, the dielectric layer 204 may be etched. For example, an etch tool 108 may etch a portion of the dielectric layer 204. In some implementations, an etch tool 108 uses a wet etch technique, a dry etch technique, a plasma-enhanced etch technique, and/or another type of etch technique to etch the portion of the dielectric layer 204. The dielectric layer 204 may be patterned using the mask 302, which results in curvature near an edge of the mask 302.

As shown in FIG. 4C, the mask 302 may be removed. For example, a photoresist removal tool 114 may remove remaining portions of the mask 302 (e.g., using a chemical stripper, a plasma asher, and/or another technique) after an etch tool 108 etches the dielectric layer 204.

As shown in FIG. 4D, the dielectric layer 204 may be etched again. For example, an etch tool 108 may etch an additional portion of the dielectric layer 204. In some implementations, an etch tool 108 uses a wet etch technique, a dry etch technique, a plasma-enhanced etch technique, and/or another type of etch technique to etch the additional portion of the dielectric layer 204. The dielectric layer 204 may be patterned without the mask 302, which results in an inflection point in the dielectric layer 204.

As shown in FIG. 4E, a piezo-electric layer 210a may be formed. For example, a deposition tool 102 may form the piezo-electric layer 210a over and/or on the frontside surface of the dielectric layer 204. In some implementations, a deposition tool 102 forms the piezo-electric layer 210a using a spin-coating technique, a CVD technique, a PVD technique, an ALD technique, and/or another deposition technique.

As shown in FIG. 4F, a bottom electrode 208a may be formed. For example, a deposition tool 102 may form the bottom electrode 208a over and/or on a frontside surface of the piezo-electric layer 210a. In some implementations, a deposition tool 102 forms the bottom electrode 208a using a spin-coating technique, a CVD technique, a PVD technique, an ALD technique, and/or another deposition technique.

As shown in FIG. 4G, a break is formed in the bottom electrode 208a. The break may separate a non-sensing portion (e.g., a portion including the inflection point and curving upward in the example implementation 400) from a sensing portion. In some implementations, a deposition tool 102 may form a photoresist layer over and/or on the frontside surface of the bottom electrode 208a, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch (e.g., use a wet etch technique, a dry etch technique, a plasma-enhanced etch technique, and/or another type of etch technique) the break in the bottom electrode 208a. Accordingly, a surface of the piezo-electric layer 210a may be exposed at the break. A photoresist removal tool 114 may remove remaining portions of the photoresist layer (e.g., using a chemical stripper, a plasma asher, and/or another technique) after the break is formed. In some implementations, the exposed surface of the piezo-electric layer 210a at the break may be cleaned (e.g., using plasma) to reduce oxidation of the piezo-electric layer 210a at the break.

As shown in FIG. 4H, a piezo-electric layer 210b may be formed. For example, a deposition tool 102 may form the piezo-electric layer 210b over and/or on the frontside surface of the bottom electrode 208a. In some implementations, a deposition tool 102 forms the piezo-electric layer 210b using a spin-coating technique, a CVD technique, a PVD technique, an ALD technique, and/or another deposition technique. Because of the break in the bottom electrode 208a, the piezo-electric layers 210a and 210b may contact each other at the break. For example, the piezo-electric layers 210a and 210b may include crystalline layers that are continuous (or at least interface with each other) at the break.

As shown in FIG. 4I, a middle electrode 208b may be formed. For example, a deposition tool 102 may form the middle electrode 208b over and/or on a frontside surface of the piezo-electric layer 210b. In some implementations, a deposition tool 102 forms the middle electrode 208b using a spin-coating technique, a CVD technique, a PVD technique, an ALD technique, and/or another deposition technique.

As shown in FIG. 4J, a break is formed in the middle electrode 208b. The break may separate the non-sensing portion (e.g., the portion including the inflection point and curving upward in the example implementation 400) from the sensing portion. In some implementations, a deposition tool 102 may form a photoresist layer over and/or on the frontside surface of the middle electrode 208b, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch (e.g., use a wet etch technique, a dry etch technique, a plasma-enhanced etch technique, and/or another type of etch technique) the break in the middle electrode 208b. Accordingly, a surface of the piezo-electric layer 210b may be exposed at the break. A photoresist removal tool 114 may remove remaining portions of the photoresist layer (e.g., using a chemical stripper, a plasma asher, and/or another technique) after the break is formed. In some implementations, the exposed surface of the piezo-electric layer 210b at the break may be cleaned (e.g., using plasma) to reduce oxidation of the piezo-electric layer 210b at the break.

As shown in FIG. 4K, a piezo-electric layer 210c may be formed. For example, a deposition tool 102 may form the piezo-electric layer 210c over and/or on the frontside surface of the middle electrode 208b. In some implementations, a deposition tool 102 forms the piezo-electric layer 210c using a spin-coating technique, a CVD technique, a PVD technique, an ALD technique, and/or another deposition technique. Because of the break in the middle electrode 208b, the piezo-electric layers 210b and 210c may contact each other at the break. For example, the piezo-electric layers 210b and 210c may include crystalline layers that are continuous (or at least interface with each other) at the break.

Although the electrode 208b is described as a middle electrode in the example implementation 400, other examples may include only two electrodes such that the electrode 208b functions as a top electrode. Therefore, operations described in connection with FIGS. 4L-4N may be omitted.

As shown in FIG. 4L, a top electrode 208c may be formed. For example, a deposition tool 102 may form the top electrode 208c over and/or on a frontside surface of the piezo-electric layer 210c. In some implementations, a deposition tool 102 forms the top electrode 208c using a spin-coating technique, a CVD technique, a PVD technique, an ALD technique, and/or another deposition technique.

As shown in FIG. 4M, a break is formed in the top electrode 208c. The break may separate the non-sensing portion (e.g., the portion including the inflection point and curving upward in the example implementation 400) from the sensing portion. In some implementations, a deposition tool 102 may form a photoresist layer over and/or on the frontside surface of the top electrode 208c, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch (e.g., use a wet etch technique, a dry etch technique, a plasma-enhanced etch technique, and/or another type of etch technique) the break in the top electrode 208c. Accordingly, a surface of the piezo-electric layer 210c may be exposed at the break. A photoresist removal tool 114 may remove remaining portions of the photoresist layer (e.g., using a chemical stripper, a plasma asher, and/or another technique) after the break is formed. In some implementations, the exposed surface of the piezo-electric layer 210c at the break may be cleaned (e.g., using plasma) to reduce oxidation of the piezo-electric layer 210c at the break.

As shown in FIG. 4N, a piezo-electric layer 210d may be formed. For example, a deposition tool 102 may form the piezo-electric layer 210d over and/or on the frontside surface of the top electrode 208c. In some implementations, a deposition tool 102 forms the piezo-electric layer 210d using a spin-coating technique, a CVD technique, a PVD technique, an ALD technique, and/or another deposition technique. Because of the break in the top electrode 208c, the piezo-electric layers 210c and 210d may contact each other at the break. For example, the piezo-electric layers 210c and 210d may include crystalline layers that are continuous (or at least interface with each other) at the break.

As shown in FIG. 4O, the dielectric layer 204 may be removed from under a portion of a piezo-electric membrane (e.g., formed by the stack of electrodes 208a, 208b, and 208c and piezo-electric layers 210a, 210b, 210c, and 210d). For example, an etch tool 108 may etch the portion of the dielectric layer 204 under the non-sensing portion. In some implementations, an etch tool 108 uses a wet etch technique, a dry etch technique, a plasma-enhanced etch technique, and/or another type of etch technique to etch the portion of the dielectric layer 204. Conformal deposition of the electrodes 208a, 208b, and 208c and the piezo-electric layers 210a, 210b, 210c, and 210d results in a semiconductor stack that still retains the approximate S-shape patterned into the dielectric layer 204. Therefore, as shown in FIG. 4O, the non-sensing portion of the semiconductor structure curves upward relative to the sensing portion.

As shown in FIG. 4P, a contact 214a may be formed to contact the electrode layer 208a in the semiconductor stack, and a contact 214b may be formed to contact the electrode layer 208c in the semiconductor stack. The contacts 214a and 214b may be formed in the sensing portion of the semiconductor structure (that is, a portion of the piezo-electric membrane configured to be stationary). For example, an etch tool 108 may etch the portion of the semiconductor stack in the sensing portion. In some implementations, an etch tool 108 uses a wet etch technique, a dry etch technique, a plasma-enhanced etch technique, and/or another type of etch technique to etch the portion of the semiconductor stack. A deposition tool 102 may form the contacts 214a and 214b. Although the example implementation 300 depicts two contacts, other contacts may be formed at different parts of the sensing portion of the semiconductor structure (e.g., at different petals, as described below).

Additionally, the semiconductor structure may be cut into a plurality of petals (e.g., as described in connection with FIG. 2B). For example, from a top-down view, a singulation tool 116 may cut the piezo-membrane into the plurality of petals. A singulation tool 116 may dice or otherwise separate the plurality of petals from each other. Alternatively, an etch tool 108 may use a wet etch technique, a dry etch technique, a plasma-enhanced etch technique, and/or another type of etch technique to separate the plurality of petals from each other.

As indicated above, FIGS. 4A-4P are provided as an example. Other examples may differ from what is described with regard to FIGS. 4A-4P. For example, the dielectric layer 204 may be supported by a substrate 202, as described in connection with FIGS. 2A and 2C. The substrate 202 may be formed after operations described in connection with FIGS. 4A-4P. Alternatively, the dielectric layer 204 may be formed on the substrate 202 such that a portion of the substrate 202 is removed from under the portion of the semiconductor stack that is configured to move in response to sound waves (e.g., similarly as described in connection with FIG. 4O).

Additionally, or alternatively, the mask 302 may be patterned such that a plurality of curvatures are formed in the dielectric layer 204 during a first etch process (e.g., as described in connection with FIG. 4B). Therefore, a plurality of inflection points are formed in the dielectric layer 204 during a second etch process (e.g., as described in connection with FIG. 4D).

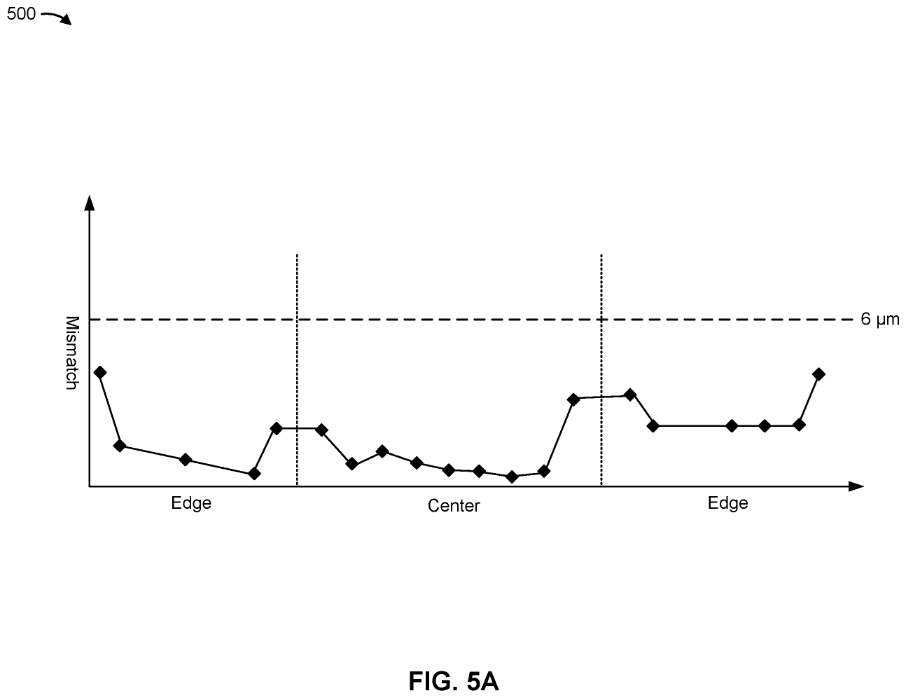

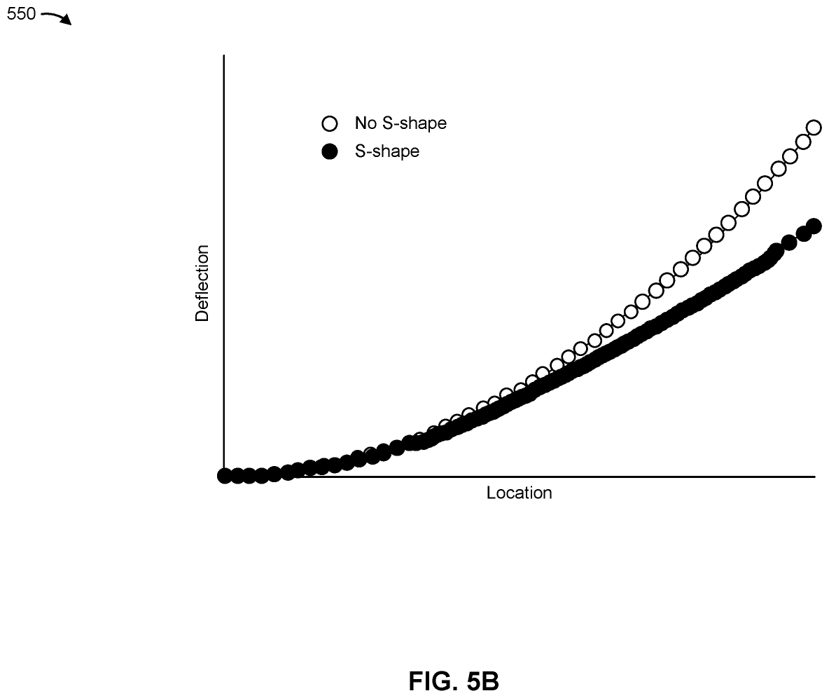

FIG. 5A is a diagram of an example graph 500 of mismatches in example semiconductor structures described herein. As shown in FIG. 5A, the mismatches are largest at edges of the structures as compared with centers. As further shown in FIG. 5A, the approximate S-shapes described herein result in mismatches that do not exceed 6 μm.

FIG. 5B is a diagram of an example graph 550 of deflections in example semiconductor structures described herein. As shown in FIG. 5B, the deflections are largest at ends of non-sensing portions of the structures. As further shown in FIG. 5B, the approximate S-shapes described herein reduce deflections (e.g., below 7.2 μm).

As indicated above, FIGS. 5A-5B are provided as examples. Other examples may differ from what is described with regard to FIGS. 5A-5B.

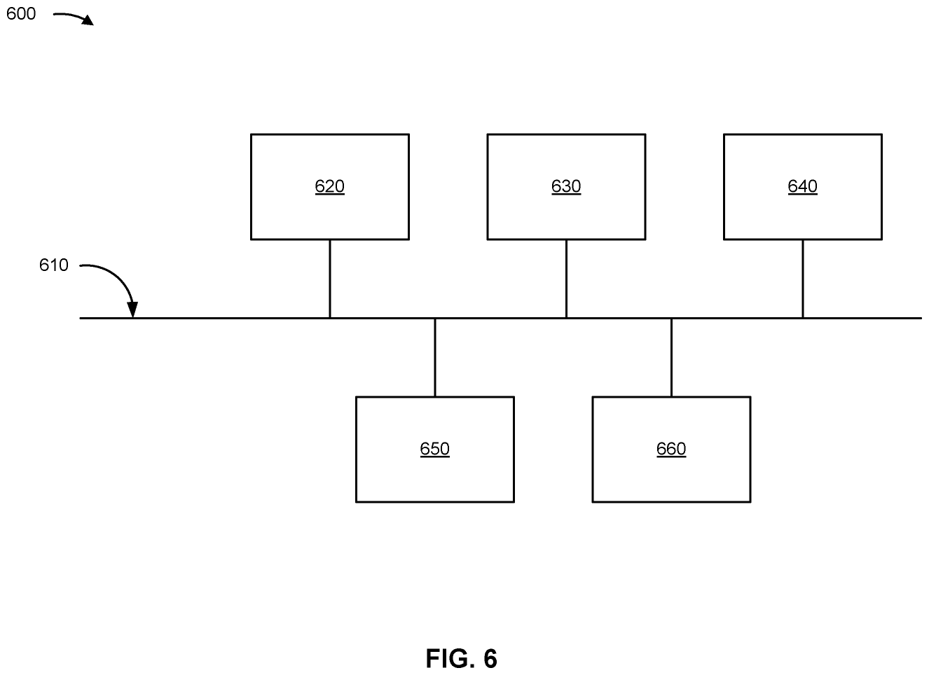

FIG. 6 is a diagram of example components of a device 600 described herein. In some implementations, one or more of the semiconductor processing tools 102-116 and/or the wafer/die transport tool 118 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

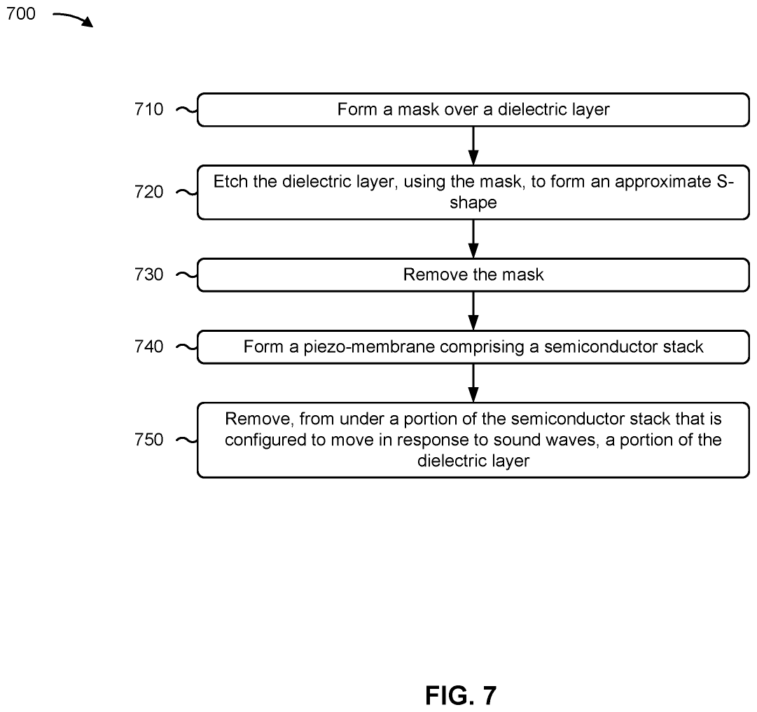

FIG. 7 is a flowchart of an example process 700 associated with forming a MEMS microphone. In some implementations, one or more process blocks of FIG. 7 are performed using one or more semiconductor processing tools (e.g., one or more of the semiconductor processing tools 102-116). Additionally, or alternatively, one or more process blocks of FIG. 7 may be performed using one or more components of device 600, such as processor 620, memory 630, input component 640, output component 650, and/or communication component 660.

As shown in FIG. 7, process 700 may include forming a mask over a dielectric layer (block 710). For example, one or more of the semiconductor processing tools 102-116 may be used to form a mask 302 over a dielectric layer 204, as described herein.

As further shown in FIG. 7, process 700 may include etching the dielectric layer, using the mask, to form an approximate S-shape (block 720). For example, one or more of the semiconductor processing tools 102-116 may be used to etch the dielectric layer 204, using the mask 302, to form an approximate S-shape, as described herein.

As further shown in FIG. 7, process 700 may include removing the mask (block 730). For example, one or more of the semiconductor processing tools 102-116 may be used to remove the mask 302, as described herein.

As further shown in FIG. 7, process 700 may include forming a piezo-membrane comprising a semiconductor stack (block 740). For example, one or more of the semiconductor processing tools 102-116 may be used to form a piezo-membrane 206 comprising a semiconductor stack 208/210, as described herein.

As further shown in FIG. 7, process 700 may include removing, from under a portion of the semiconductor stack that is configured to move in response to sound waves, a portion of the dielectric layer (block 750). For example, one or more of the semiconductor processing tools 102-116 may be used to remove, from under a portion 206b of the semiconductor stack 208/210 that is configured to move in response to sound waves, a portion of the dielectric layer 204, as described herein.

Process 700 may include additional implementations, such as any single implementation or any combination of implementations described below and/or in connection with one or more other processes described elsewhere herein.

In a first implementation, etching the dielectric layer 204 includes performing a first etch process using the mask 302 and performing a second etch process after removing the mask 302.

In a second implementation, alone or in combination with the first implementation, forming the piezo-membrane 206 includes forming a first piezo-electric layer 210a, forming a bottom electrode 208a over the first piezo-electric layer 210a, forming a second piezo-electric layer 210b over the bottom electrode 208a, forming a top electrode 208b over the second piezo-electric layer 210b, and forming a third piezo-electric layer 210c over the top electrode 208b.

In a third implementation, alone or in combination with one or more of the first and second implementations, forming the bottom electrode 208a includes depositing the bottom electrode 208a and etching a break in the bottom electrode 208a between the portion 206b of the semiconductor stack 208/210 that is configured to move in response to sound waves and a portion 206a of the semiconductor stack 208/210 that is configured to be stationary, such that the first piezo-electric layer 210a and the second piezo-electric layer 210b are continuous at the break.

In a fourth implementation, alone or in combination with one or more of the first through third implementations, forming the top electrode 208b includes depositing the top electrode 208b and etching a break in the top electrode 208b between the portion 206b of the semiconductor stack 208/210 that is configured to move in response to sound waves and a portion 206a of the semiconductor stack 208/210 that is configured to be stationary, such that the second piezo-electric layer 210b and the third piezo-electric layer 210c are continuous at the break.

In a fifth implementation, alone or in combination with one or more of the first through fourth implementations, process 700 includes dicing the piezo-membrane 206 into a plurality of petals 216.

In a sixth implementation, alone or in combination with one or more of the first through fifth implementations, process 700 includes forming, in a portion 206a of the semiconductor stack 208/210 that is configured to be stationary, a plurality of contacts 214 that contact a plurality of electrode layers 208 in the semiconductor stack 208/210.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, an approximate S-shape is formed in a non-sensing portion of a MEMS microphone. For example, a piezo-electric layer, in a semiconductor stack forming the non-sensing portion, may have a lower portion at a first point that is at least 1 μm below the lower portion at a second point. The approximately S-shape reinforces a piezo-membrane including the non-sensing portion and results in mismatch between petals of the piezo-membrane remaining closer to zero (e.g., within 6 μm). As a result, fewer incoming sound waves leak through a gap between petals of the piezo-membrane, and performance of the MEMS microphone is increased. Additionally, the gap between the petals is less likely to allow dust and other small particles to enter the MEMS microphone, which further improves performance of the MEMS microphone.

As described in greater detail above, some implementations described herein provide a semiconductor structure. The semiconductor structure includes at least one dielectric support and a piezo-membrane. The piezo-membrane includes a plurality of piezo-electric layers interleaved with a plurality of electrode layers. The piezo-membrane includes a first portion, supported by the at least one dielectric support, and a second portion arranged to move in response to sound waves. The second portion includes an approximate S-shape relative to the first portion.

As described in greater detail above, some implementations described herein provide a method. The method includes forming a mask over a dielectric layer. The method includes etching the dielectric layer, using the mask, to form an approximate S-shape. The method includes removing the mask. The method includes forming a piezo-membrane that includes a semiconductor stack. The method includes removing, from under a portion of the semiconductor stack that is configured to move in response to sound waves, a portion of the dielectric layer.

As described in greater detail above, some implementations described herein provide a semiconductor device. The semiconductor device includes a sensing portion, of the semiconductor device, that includes a stationary portion of a piezo-membrane. The semiconductor device includes a non-sensing portion, of the semiconductor device, that includes a flexible portion of the piezo-membrane. The non-sensing portion includes a semiconductor stack having a lower portion at a first point that is at least 1 micrometer (μm) below the lower portion at a second point.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
at least one dielectric support; and
a piezo-membrane comprising a plurality of piezo-electric layers interleaved with a plurality of electrode layers, wherein the piezo-membrane includes:
a first portion supported by the at least one dielectric support, and
a second portion arranged to move in response to sound waves,
wherein the second portion includes an approximate S-shape relative to the first portion.

2. The semiconductor structure of claim 1, wherein the piezo-membrane is further divided into a plurality of petals.

3. The semiconductor structure of claim 2, wherein a mismatch associated with the plurality of petals is in a range from 0.0 micrometers (μm) to approximately 5.0 μm.

4. The semiconductor structure of claim 2, wherein each petal, of the plurality of petals, includes the approximate S-shape.

5. The semiconductor structure of claim 1, wherein the plurality of piezo-electric layers comprises a nitride material.

6. The semiconductor structure of claim 1, wherein the plurality of electrode layers comprises molybdenum.

7. The semiconductor structure of claim 1, further comprising:
a silicon-based region supporting the at least one dielectric support.

8. A method, comprising:
forming a mask over a dielectric layer;
etching the dielectric layer, using the mask, to form an approximate S-shape;
removing the mask;
forming a piezo-membrane comprising a semiconductor stack; and
removing, from under a portion of the semiconductor stack that is configured to move in response to sound waves, a portion of the dielectric layer.

9. The method of claim 8, wherein etching the dielectric layer comprises:
performing a first etch process using the mask; and
performing a second etch process after removing the mask.

10. The method of claim 8, wherein forming the piezo-membrane comprises:
forming a first piezo-electric layer;
forming a bottom electrode over the first piezo-electric layer;
forming a second piezo-electric layer over the bottom electrode;
forming a top electrode over the second piezo-electric layer; and
forming a third piezo-electric layer over the top electrode.

11. The method of claim 10, wherein forming the bottom electrode comprises:
depositing the bottom electrode; and
etching a break in the bottom electrode between the portion of the semiconductor stack that is configured to move in response to sound waves and a portion of the semiconductor stack that is configured to be stationary,
wherein the first piezo-electric layer and the second piezo-electric layer are continuous at the break.

12. The method of claim 10, wherein forming the top electrode comprises:
depositing the top electrode; and
etching a break in the top electrode between the portion of the semiconductor stack that is configured to move in response to sound waves and a portion of the semiconductor stack that is configured to be stationary,
wherein the second piezo-electric layer and the third piezo-electric layer are continuous at the break.

13. The method of claim 8, further comprising:
dicing the piezo-membrane into a plurality of petals.

14. The method of claim 8, further comprising:
forming, in a portion of the semiconductor stack that is configured to be stationary, a plurality of contacts that contact a plurality of electrode layers in the semiconductor stack.

15. A semiconductor device, comprising:
a sensing portion, of the semiconductor device, comprising a stationary portion of a piezo-membrane; and
a non-sensing portion, of the semiconductor device, comprising a flexible portion of the piezo-membrane,
wherein the non-sensing portion includes a semiconductor stack having a lower portion at a first point that is at least 1 micrometer (μm) below the lower portion at a second point.

16. The semiconductor device of claim 15, further comprising:
a circular dielectric region supporting the non-sensing portion of the semiconductor device.

17. The semiconductor device of claim 16, further comprising:
a circular silicon-based region supporting the circular dielectric region.

18. The semiconductor device of claim 15, wherein an electrode layer in the piezo-membrane is non-continuous between the stationary portion and the flexible portion.

19. The semiconductor device of claim 15, wherein the lower portion of the non-sensing portion at a third point is at least 1 μm below the lower portion at the second point.

20. The semiconductor device of claim 15, further comprising:
a plurality of contacts that contact the sensing portion of the piezo-membrane.
